(19) United States
(12) Patent Application Publication
(10) Pub. No.: US 2025/0301809 A1
(43) Pub. Date: Sep. 25, 2025

(54) IMAGE SENSOR

(71) Applicant: Samsung Electronics Co., Ltd., Suwon-si, (KR)

(72) Inventors: Yeaju JANG, Suwon-si (KR); Hyungeun YOO, Suwon-si (KR); Yun Ki LEE, Suwon-si (KR)

(73) Assignee: Samsung Electronics Co., Ltd., Suwon-si, Gyeonggi-do (KR)

(21) Appl. No.: 19/087,846

(22) Filed: Mar. 24, 2025

(30) Foreign Application Priority Data
Mar. 22, 2024 (KR) 10-2024-0039899

(51) Int. Cl. H10F 39/00; H10F 39/18

(52) U.S. Cl. CPC H10F 39/8053; H10F 39/182

(57) ABSTRACT

The present disclosure relates to an image sensor. The image sensor according to at least one embodiment includes a substrate, a plurality of photodiodes in the substrate, a color filter layer including a lower color filter layer and an upper color filter layer sequentially stacked on the plurality of photodiodes, and a micro lens layer disposed on the color filter layer, wherein the lower color filter layer includes a plurality of lower color filters having at least one color of first to fourth colors, and the upper color filter layer includes a plurality of upper color filters having at least one color of the first to fourth colors such that the color filter layer includes a plurality of color filters and at least some of the plurality of color filters have colors different from the first to fourth colors.

### CROSS-REFERENCE TO RELATED APPLICATION

This application claims priority to and the benefit of Korean Patent Application No. 10-2024-0039899 filed in the Korean Intellectual Property Office on Mar. 22, 2024, the entire contents of which are incorporated herein by reference.

### BACKGROUND OF THE DISCLOSURE

### 1. Field

The present disclosure relates to an image sensor.

### 2. Description of the Related Art

Complementary metal-oxide semiconductor (CMOS) image sensors are solid-state imaging devices that use complementary metal-oxide semiconductors to convert light into image data. CMOS image sensors have lower manufacturing costs compared to charge-coupled devices (CCD) image sensors. In addition, CMOS image sensors may have a smaller size compared to CCD image sensors having a high-voltage analog circuit, and thus, consume less power. As a result, CMOS image sensors are frequently used for electronic appliances including portable devices such as smartphones and digital cameras.

A pixel array included in a CMOS image sensor includes a photodiode in each pixel. The photodiode may generate an electrical signal that varies based on the quantity of incident light. The CMOS image sensor may process the electrical signal to synthesize an image.

The CMOS image sensor includes a color filter array (CFA), for example, primary or complementary color filters, and may detect color information by transmitting light with a specific wavelength band through the color filter array.

Recently, as the demand for high-resolution images has increased, a color filter array that is advantageous in terms of resolution and has a structure and arrangement capable of expressing various colors is required.

### SUMMARY

Embodiments attempt to provide an image sensor with improved optical characteristics.

An image sensor according to at least one embodiment includes a substrate, a plurality of photodiodes in the substrate, a pixel isolation pattern between the plurality of photodiodes, a color filter layer including a lower color filter layer and an upper color filter layer sequentially stacked on the plurality of photodiodes, and a micro lens layer on the color filter layer, wherein the color filter layer comprises a plurality of color filters corresponding to the plurality of photodiodes, the lower color filter layer comprises a plurality of lower color filters each having at least one color of first to fourth colors, and each of the plurality of color filters comprises a respective one of the plurality of lower color filters, and the upper color filter layer comprises a plurality of upper color filters each having at least one color of the first to fourth colors, and at least some of the plurality of color filters further comprise a respective one of the plurality of upper color filters, and at least some of the plurality of color filters have colors different from the first to fourth colors.

An image sensor according to at least one embodiment includes a substrate, a plurality of photodiodes in the substrate, a pixel isolation pattern between the plurality of photodiodes, a color filter layer including a lower color filter layer and an upper color filter layer sequentially stacked on the plurality of photodiodes, and a micro lens layer on the color filter layer, wherein the color filter layer comprises a plurality of color filters corresponding to the plurality of photodiodes, the lower color filter layer comprises a plurality of lower color filters each having at least one color of white, yellow, magenta, or cyan, and each of the plurality of color filters comprises a respective one of the plurality lower color filters, the upper color filter layer comprises a plurality of upper color filters each having at least one color of the white, the yellow, the magenta, or the cyan, and each of the plurality of color filters comprises a respective one of the plurality upper color filters, at least some of the plurality of color filters have a different color from the white filter, the yellow filter, the magenta filter, and the cyan filter, and each of the plurality of color filters has substantially the same thickness.

An image sensor according to at least one embodiment include a substrate, a plurality of photodiodes in the substrate, a pixel isolation pattern between the plurality of photodiodes, a color filter layer including a lower color filter layer and an upper color filter layer sequentially stacked on the plurality of photodiodes, and a micro lens layer on the color filter layer, wherein the micro lens layer includes a flat part covering the color filter layer and a plurality of micro lenses on the flat part, the color filter layer comprises a plurality of color filters corresponding to the plurality of photodiodes, the lower color filter layer comprises a plurality of lower color filters each having at least one color of yellow, magenta, and cyan, and each of the plurality of color filters comprises a respective one of the plurality of lower color filters, the upper color filter layer comprises a plurality of upper color filters each having at least one color of the yellow, the magenta, and the cyan, and at least some of the plurality of color filters comprise a respective one of the plurality of upper color filters, at least some of the plurality of color filters have a different color from the yellow filter, the magenta filter, and the cyan filter, and a thickness of at least one of the plurality of color filters is different from a thickness of another one of the plurality of color filters.

According to embodiments, since the color filter layer disposed on the plurality of pixels includes a lower color filter layer and an upper color filter layer including complementary color filters, the plurality of color filters included in the color filter layer may have various colors.

Accordingly, the accuracy, sensitivity, and resolution of imaging of a plurality of pixels included in an image sensor may be improved.

### BRIEF DESCRIPTION OF THE DRAWINGS

FIG. 1 is a block diagram of an image sensor according to at least one embodiment.

FIG. 2 is a top plan view of an image sensor according to at least one embodiment.

FIG. 3 is a perspective view illustrating a color filter layer included in an image sensor according to at least one embodiment.

FIGS. 4 and 5 are exploded perspective views of a color filter layer included in an image sensor according to some embodiments.

FIG. 6 is a cross-sectional view taken along line I-I′ of FIG. 2.

FIG. 7 is a top plan view of an image sensor according to some embodiments.

FIG. 8 is a perspective view of a color filter layer included in the image sensor shown in FIG. 7.

FIGS. 9 to 11 are exploded perspective views of the color filter layer shown in FIG. 8 according to some embodiments.

FIG. 12 is a top plan view of an image sensor according to some embodiments.

FIG. 13 is a perspective view of a color filter layer included in the image sensor shown in FIG. 12.

FIG. 14 is an exploded perspective view of the color filter layer shown in FIG. 13.

FIG. 15 is a perspective view of a color filter layer included in an image sensor according to some embodiments.

FIG. 16 is an exploded perspective view of the color filter layer shown in FIG. 15.

FIG. 17 is a top plan view of an image sensor according to some embodiments.

FIG. 18 is a perspective view of a color filter layer included in the image sensor of FIG. 17.

FIG. 19 is an exploded perspective view of the color filter layer shown in FIG. 18.

FIG. 20 is a cross-sectional view taken along line II-II′ of FIG. 17.

FIGS. 21 and 23 are perspective views of color filter layers included in an image sensor according to some embodiments.

FIG. 22 is an exploded perspective view of the color filter layer shown in FIG. 21.

FIG. 24 is an exploded perspective view of the color filter layer shown in FIG. 23.

FIG. 25 is a top plan view of an image sensor according to some embodiments.

### DETAILED DESCRIPTION

The present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification. In the disclosure, terms such as “-or/er”, “circuit”, etc. may be used to denote a unit that has at least one function or operation and is implemented with processing circuitry, such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

Size and thickness of each constituent element in the drawings are arbitrarily illustrated for better understanding and ease of description, the following embodiments are not limited thereto. In the drawings, the thickness of layers, films, panels, regions, etc., are exaggerated for clarity. In the drawings, the thickness of some layers and regions may be exaggerated for ease of description. Additionally, when the terms “about” or “substantially” are used in this specification in connection with a numerical value and/or geometric terms, it is intended that the associated numerical value includes a manufacturing tolerance (e.g., +10%) around the stated numerical value. Further, regardless of whether numerical values and/or geometric terms are modified as “about” or “substantially,” it will be understood that these values should be construed as including a manufacturing or operational tolerance (e.g., +10%) around the stated numerical values and/or geometry. Additionally, whenever a range of values is enumerated, the range includes all values within the range as if recorded explicitly clearly, and may further include the boundaries of the range. Accordingly, the range of “X” to “Y” includes all values between X and Y, including X and Y.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily referred to as being positioned “on” or “above” in a direction opposite to gravity, but intended to encompass different orientations of the device in use or operation in addition to the orientation depicted in the figures, and that the device may be otherwise oriented (rotated 90 degrees or at other orientations) and the spatially relative terms used herein interpreted accordingly.

In addition, unless explicitly described to the contrary, the word “comprise,” and variations such as “comprises” or “comprising,” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

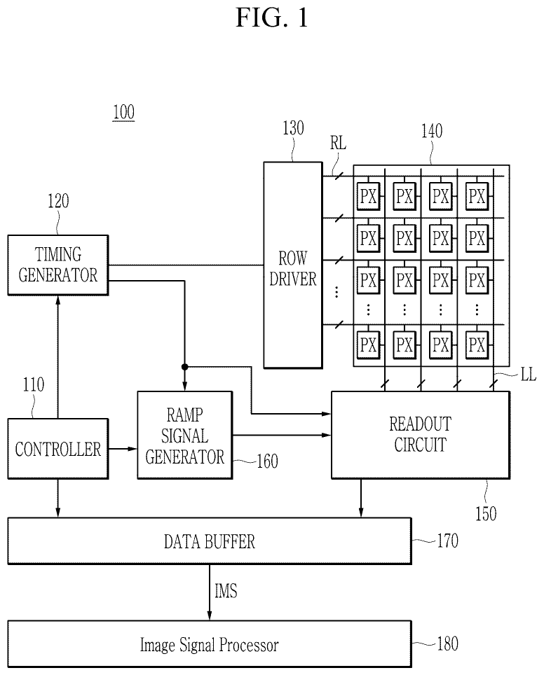

Hereinafter, an image sensor according to at least one embodiment will be described with reference to FIGS. 1 to 6.

FIG. 1 is a block diagram of an image sensor according to at least one embodiment.

Referring to FIG. 1, an image sensor 100 according to at least one embodiment may include a controller 110, a timing generator 120, a row driver 130, a pixel array 140, a readout circuit 150, and a ramp signal generator 160, a data buffer 170, and an image signal processor 180. In at least one embodiment, the image signal processor 180 may be disposed outside the image sensor 100.

The image sensor 100 may be configured to generate an image signal by converting light received from the outside into an image signal IMS (e.g., an electrical signal). The image signal IMS may be provided to the image signal processor 180.

The image sensor 100 may be mounted on an electronic device having an image and/or light sensing function. For example, the image sensor 100 may be mounted on electronic devices such as cameras, smartphones, wearable devices, internet of things (IoT) devices, home appliances, tablet PCs (Personal Computers), personal digital assistant (PDA), portable multimedia player (PMP), navigation, drones, advanced driver assistance systems (ADAS), etc. Alternatively, the image sensor 100 may be mounted on electronic devices that are included as components in vehicles, furniture, manufacturing facilities, doors, and various measuring devices.

The controller 110 may be configured to generally control each component 120, 130, 150, 160, and 170 included in the image sensor 100. The controller 110 may control the operation timing of each component 120, 130, 150, 160, and 170 using control signals. In at least one embodiment, the controller 110 may receive a mode signal indicating an imaging mode from an application processor, and generally control the image sensor 100 based on the received mode signal. For example, an application processor (not illustrated) may determine the imaging mode of the image sensor 100 according to various scenarios (such as the illumination of the imaging environment, the user's resolution setting, and the sensed or learned state) and may provide the determined result to the controller 110 as a mode signal. The controller 110 may control a plurality of pixels of the pixel array 140 to output pixel signals according to the imaging mode. The pixel array 140 may output a pixel signal for each of the plurality of pixels and pixel signals for some of the plurality of pixels. The readout circuit 150 may be configured to sample and process pixel signals received from the pixel array 140. The timing generator 120 may be configured to generate a signal that serves as a reference for the operation timing of the components of the image sensor 100. For example, the timing generator 120 may control the timing of the row driver 130, the readout circuit 150, and the ramp signal generator 160. The timing generator 120 may provide a control signal that controls the timing of the row driver 130, the readout circuit 150, and the ramp signal generator 160.

The pixel array 140 may include a plurality of pixels PX, a plurality of row lines RL respectively connected to the plurality of pixels PX, and a plurality of column lines LL. In at least one embodiment, each pixel PX may include at least one photoelectric conversion element. A photoelectric conversion element may detect incident light and convert the incident light into an electrical signal according to the amount of light, that is, a plurality of analog pixel signals. The photoelectric conversion element may be a photodiode, a pinned diode, and/or the like.

Additionally, the photoelectric conversion element may be a single-photon avalanche diode SPAD applied to a 3D sensor pixel. The level of the analog pixel signal output from the photoelectric conversion element may be proportional to the amount of charge output from the photoelectric conversion element. For example, the level of the analog pixel signal output from the photoelectric conversion element may be determined according to the amount of light received into the pixel array 140.

The plurality of row lines RL extend in a first direction and may be connected to pixels PX arranged along the first direction. For example, a control signal output from the row driver 130 to the row line RL may be transmitted to the gates of transistors of the plurality of pixels PX connected to the row line RL. The column line LL extends in a second direction crossing the first direction and may be connected to the plurality of pixels PX arranged along the second direction. A plurality of pixel signals output from the plurality of pixels PX may be transmitted to the readout circuit 150 through the plurality of column lines CL.

A color filter layer and a micro lens layer may be disposed on the pixel array 140. The micro lens layer may include a plurality of micro lenses, and at least one pixel PX corresponding to each of the plurality of micro lenses may be disposed.

The color filter layer may include color filters such as red, green, and blue, and may additionally include white and complementary colors. For one pixel PX, a color filter of one color may be disposed between the pixel PX and the corresponding micro lens.

The row driver 130 may generate a control signal for driving the pixel array 140 in response to a control signal from the timing generator 120, and provide the control signal to the plurality of pixels PX of the pixel array 140 through the plurality of row lines RL.

In at least one embodiment, the row driver 130 may control the pixel PX to sense incident light in row line units. A row line unit may include at least one row line RL. For example, the row driver 130 may provide a transmission signal, a reset signal, a selection signal, etc. to the pixel array 140.

The readout circuit 150 may be configured to convert a pixel signal (or electric signal) from the pixel PX connected to the row line RL selected from among the plurality of pixels PX into a pixel value representing the quantity of light in response to a control signal from the timing generator 120. The readout circuit 150 may convert a pixel signal output through a corresponding column line CL into a pixel value. For example, the readout circuit 150 may convert a pixel signal into a pixel value by comparing the ramp signal and the pixel signal. The pixel value may be image data having a plurality of bits. Specifically, the readout circuit 150 may include a selector, a plurality of comparators, and a plurality of counter circuits.

The ramp signal generator 160 may be configured to generate a reference signal and transmit the reference signal to the readout circuit 150.

The ramp signal generator 160 may include a current source, a resistor, and a capacitor. The ramp signal generator 160 may generate a plurality of ramp signals that fall or rise with a slope determined according to the current size of the variable current source or the resistance value of the variable resistor, by adjusting the ramp voltage applied to the ramp resistance by controlling the current size of the variable current source or the resistance value of the variable resistor.

The data buffer 170 may be configured to store pixel values of the plurality of pixels PX connected to the selected column line LL transmitted from the readout circuit 150, and output the stored pixel values in response to an enable signal from the controller 110.

The image signal processor 180 may be configured to perform image signal processing on the image signal received from the data buffer 170. For example, the image signal processor 180 may receive a plurality of image signals from the data buffer 170, and generate one image by synthesizing the received image signals.

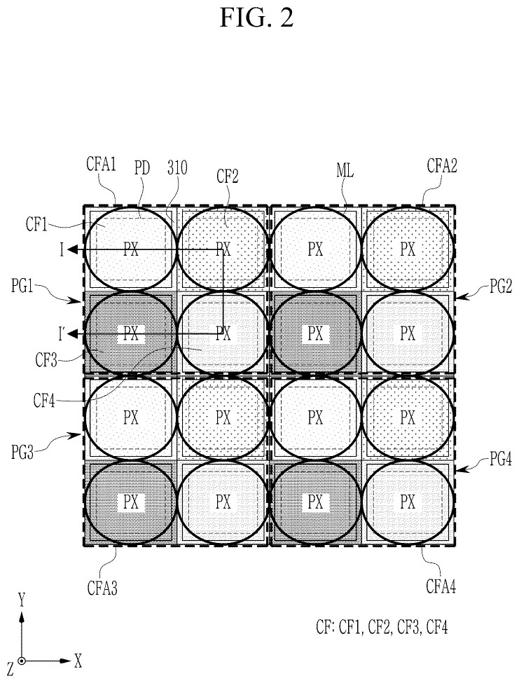

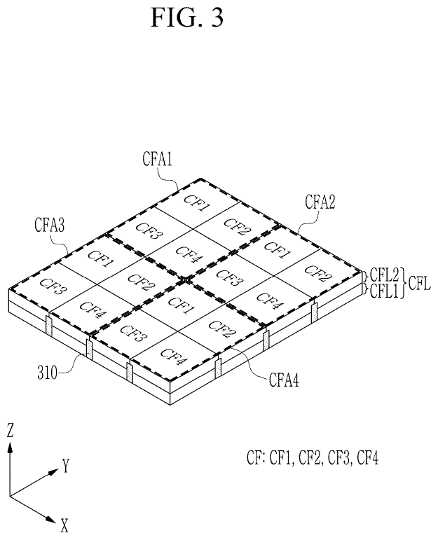

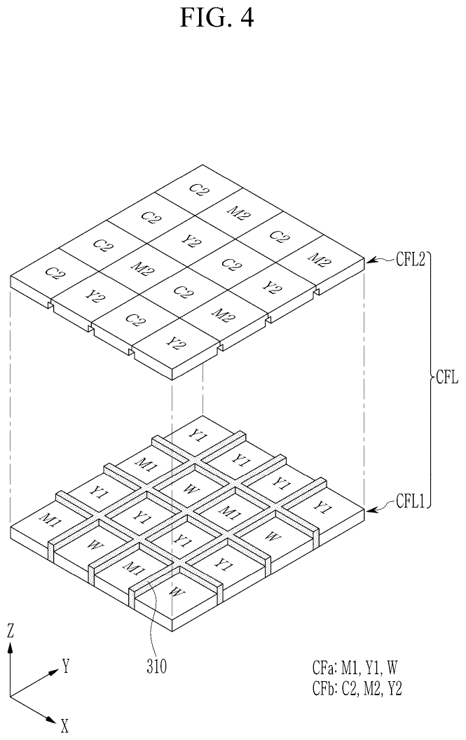

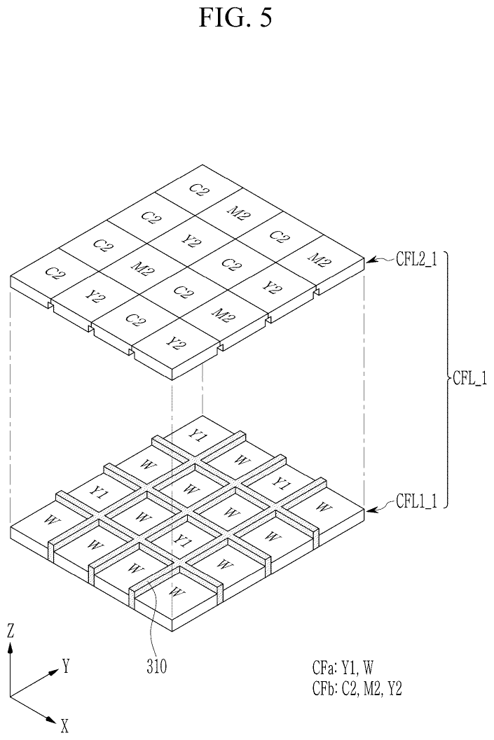

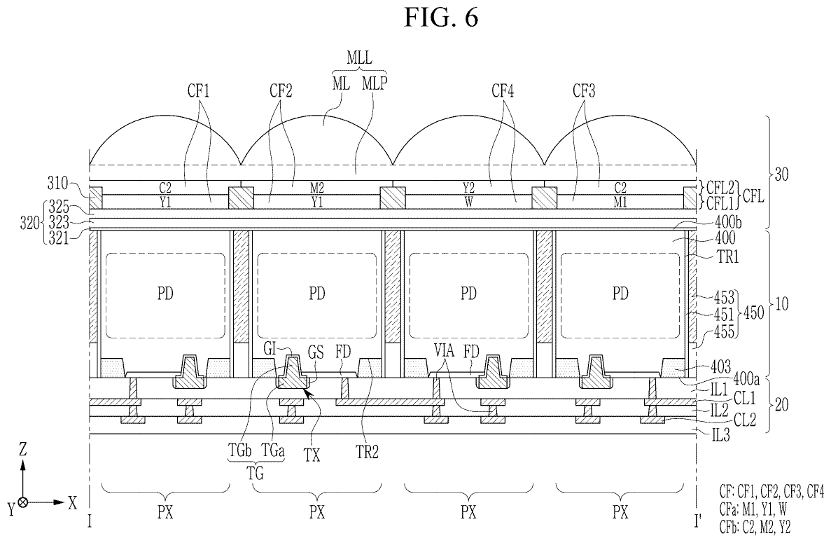

FIG. 2 is a top plan view of an image sensor according to at least one embodiment. FIG. 3 is a perspective view illustrating a color filter layer included in an image sensor according to at least one embodiment. FIGS. 4 and 5 are exploded perspective views of a color filter layer included in an image sensor according to some embodiments. FIG. 6 is a cross-sectional view taken along line I-I′ of FIG. 2.

Referring to FIGS. 2 to 6, the image sensor according to at least one embodiment may include a photoelectric conversion layer 10, a wiring region 20, and a light-transmitting layer 30.

The photoelectric conversion layer 10 may be disposed between the wiring region 20 and the light-transmitting layer 30. For example, the wiring region 20, the photoelectric conversion layer 10, and the light-transmitting layer 30 may be sequentially disposed along a third direction Z, which is a vertical direction.

The photoelectric conversion layer 10 may include a substrate 400, photodiodes PD disposed within the substrate 400, and a pixel isolation pattern 450 disposed between the photodiodes PD. Light incident from the outside may be converted into an electrical signal from each of the photodiodes PD.

The substrate 400 may include a first surface 400a and a second surface 400b facing each other in the third direction Z, which is a vertical direction. The second surface 400b of the substrate 400 may be a light-receiving surface on which light is incident.

The first wiring region 20 may be disposed on the first side 400a of the substrate 400, and the light-transmitting layer 30 may be disposed on the second surface 400b of the first substrate 400. That is, the substrate 400 may be disposed between the wiring region 20 and the light-transmitting layer 30.

The substrate 400 may be a semiconductor substrate and/or a silicon on insulator (SOI) substrate. The semiconductor substrate may include an elemental and/or a compound semiconductor, and may be, for example, a silicon substrate, a germanium substrate, a silicon-germanium substrate, and/or the like. The substrate 400 may include an impurity of the first conductivity type. For example, the first conductivity type impurity may be a p-type impurity such as aluminum (Al), boron (B), indium (In), and/or gallium (Ga).

The substrate 400 may include the plurality of pixels PX defined by the pixel isolation pattern 450. The plurality of pixels PX may output photoelectric signals from incident light incident from the outside.

The plurality of pixels PX may be arranged along rows and columns on a plane. That is, the plurality of pixels PX may be arranged in a matrix shape along rows parallel to the first direction X and columns parallel to the second direction Y on a plane.

The plurality of pixels PX may include first to fourth pixel groups PG1, PG2, PG3, and PG4. That is, the first to fourth pixel groups PG1, PG2, PG3, and PG4 may include N×M pixels PX in an N×M arrangement. The N and the M may each independently be an integer greater than 1. For example, the first to fourth pixel groups PG1, PG2, PG3, and PG4 may each include four adjacent pixels PX arranged in two rows and two columns. However, the number and arrangement of pixels PX included in one pixel group are not limited thereto and may be changed. For example, each of the first to fourth pixel groups PG1, PG2, PG3, and PG4 may include nine adjacent pixels PX arranged in three rows and three columns. As another example, each of the first to fourth pixel groups PG1, PG2, PG3, and PG4 may include 16 adjacent pixels PX arranged in four rows and four columns.

The pixel isolation pattern 450 may be disposed between the plurality of pixels PX.

The pixel isolation pattern 450 may define the plurality of pixels PX included in the first to fourth pixel groups PG1, PG2, PG3, and PG4. For example, the pixel isolation pattern 450 may have a lattice structure on a plane and may partition the plurality of pixels PX included in the first to fourth pixel groups PG1, PG2, PG3, and PG4.

As shown in FIG. 6, the pixel isolation pattern 450 may be disposed within a first trench TR1 in a cross-section.

The pixel isolation pattern 450 may be a deep trench isolation (DTI) layer. The pixel isolation pattern 450 may penetrate the substrate 400. The thickness of the pixel isolation pattern 450 may be the same as and/or substantially similar to the thickness of the substrate 400 in the vertical direction.

In FIG. 6, the width of the pixel isolation pattern 450 in the first direction X is shown to be constant within the substrate 400, but the cross-sectional shape of the pixel isolation pattern 450 is not limited thereto. For example, the pixel isolation pattern 450 may have a shape in which the width along the first direction X gradually decreases from the first surface 400a to the second surface 400b of the substrate 400.

The pixel isolation pattern 450 may include a first isolation pattern 451, a second isolation pattern 453, and a capping pattern 455.

The first isolation pattern 451 may extend along the inner surface of the first trench TR1. The first isolation pattern 451 may include a silicon-based insulating material (e.g., silicon nitride, silicon oxide, or silicon oxynitride) or a high dielectric material (e.g., hafnium oxide or aluminum oxide). As another example, the first isolation pattern 451 may include a plurality of layers, and each layer may include a different material.

The first isolation pattern 451 may have a lower refractive index than the substrate 400. However, the material included in the first isolation pattern 451 is not limited thereto. Accordingly, the crosstalk phenomenon between the pixels PX disposed on the first substrate 400 may be prevented or reduced.

The second isolation pattern 453 may be disposed on the first isolation pattern 451. Both side surfaces of the second isolation pattern 453 may be surrounded by the first isolation pattern 451. The first isolation pattern 451 may be disposed between the second isolation pattern 453 and the substrate 400. The second isolation pattern 453 may be spaced apart from the substrate 400 by the first isolation pattern 451.

Accordingly, when the image sensor 100 operates, the second isolation pattern 453 may be electrically separated from the substrate 400. The second isolation pattern 453 may include a crystalline semiconductor material such as polycrystalline silicon. In at least some embodiments, the second isolation pattern 453 may further include a dopant, and the dopant may include an impurity of the first conductivity type or an impurity of the second conductivity type. As another example, the second isolation pattern 453 may include doped polycrystalline silicon. As another example, the second isolation pattern 453 may include an undoped crystalline semiconductor material. As another example, the second isolation pattern 453 may include undoped polycrystalline silicon. The term “undoped” may refer to not performing intentional doping process. The dopant may include an n-type dopant and a p-type dopant. However, the material included in the second isolation pattern 453 is not limited thereto.

The capping pattern 455 may be disposed on the lower surface of the second isolation pattern 453. The second isolation pattern 453 and the capping pattern 455 may be disposed to overlap in the vertical direction, and the capping pattern 455 may be disposed adjacent to the first surface 400a of the substrate 400.

The capping pattern 455 may include a non-conductive material. The capping pattern 455 may include, for example, a silicon-based insulating material (e.g., silicon nitride, silicon oxide, or silicon oxynitride) and/or a high dielectric material (e.g., hafnium oxide or aluminum oxide). However, the material included in the capping pattern 455 is not limited thereto.

Accordingly, the pixel isolation pattern 450 may prevent and/or mitigate photocharges generated by incident light incident onto the pixel PX from entering another adjacent pixel PX due to random drift. That is, the pixel isolation pattern 450 may prevent and/or reduce crosstalk between pixels PX.

The plurality of photodiodes PD are disposed within the substrate 400 and may be configured to receive light. The plurality of photodiodes PD may be positioned to correspond to each of the plurality of pixels PX. That is, the plurality of photodiodes PD may have substantially the same arrangement on a plane as the plurality of pixels PX.

Light incident from the outside may be converted into electrical signals by photodiodes PD. Photodiodes PD may generate and accumulate photocharges in proportion to the intensity of incident light.

The photodiodes PD may be regions of the substrate 400 doped with the impurity of the second conductivity type. The impurity of the second conductivity type may have a conductivity type opposite to that of the impurity of the first conductivity type. The impurity of the second conductivity type may include n-type impurity such as phosphorus, arsenic, bismuth, and/or antimony.

Each of the photodiodes PD may include a first region adjacent to the first surface 400a of the substrate 400 and a second region adjacent to the second surface 400b. In at least some embodiments, there may be a difference in impurity concentration between the first region and the second region of the photodiodes PD.

Accordingly, the photodiodes PD may have a potential gradient between the first surface 400a and the second surface 400b of the substrate 400. However, in some embodiments, the photodiodes PD may not have a potential gradient between the first surface 400a and the second surface 400b of the first substrate 400.

A device isolation pattern 403 may be disposed within the substrate 400. For example, the device isolation pattern 403 may be disposed within a second trench TR2 on a cross-section. The second trench TR2 may be recessed from the first surface 400a of the substrate 400 toward the second surface 400b. The device isolation pattern 403 may be a shallow trench isolation (STI) film.

The device isolation pattern 403 may define an activation pattern. The upper surface of the device isolation pattern 403 may be disposed within the substrate 400. The width of the device isolation pattern 403 in the first direction X may gradually decrease from the first surface 400a to the second surface 400b of the substrate 400. The upper surface of the device isolation pattern 403 may be disposed to be spaced apart from the photodiodes PD.

A transmission transistor TX including a transmission gate TG may be disposed on the first surface 400a of the substrate 400. In at least one embodiment, the transmission gate TG may be a vertical type. A part of the transmission gate TG may be disposed within the substrate 400, and the remaining part may protrude onto the first surface 400a of the substrate 400.

For example, the transmission gate TG may include a first portion TGa disposed on the first surface 400a of the substrate 400, and a second portion TGb disposed within the substrate 400 and extending from the first surface 400a toward the second surface 400b of the substrate 400. However, the shape of the transmission gate TG is not limited thereto and may be changed. For example, the transmission gate TG may be of a planar type that omits the second portion TGb and includes only the first portion TGa.

Although not shown in FIG. 6, the amplification transistor and the selection transistor may be disposed on the first surface 400a of the substrate 400. For example, the gate of the amplification transistor and the gate of the selection transistor may be disposed on the first surface 400a of the substrate 400.

Additionally, although not shown in FIG. 6, a reset transistor and a dual conversion transistor may be disposed on the first surface 400a of the substrate 400. The reset transistor may include a reset gate, and the dual conversion transistor may include dual conversion gates.

Gate spacers GS may be disposed on both side surfaces of the first portion TGa of the transmission gate TG. The gate spacer GS may include, for example, silicon nitride, silicon carbonitride, or silicon oxynitride.

A gate dielectric layer GI may be disposed between the transmission gate TG and the substrate 400. For example, the gate dielectric layer GI may be disposed between the second portion TGb of the transmission gate TG and the substrate 400.

Although not shown in FIG. 6, the gate dielectric layer GI may be disposed between each of the above-described selection gate, amplification gate, dual conversion gate, and reset gate and the substrate 400, and the gate spacers GS may be disposed on both side surfaces of the above-described gates.

In some embodiments, an opposing substrate (not shown) overlapping the substrate 400 may be further included, and one or more of the amplification transistor, selection transistor, reset transistor, and dual conversion transistor may be disposed on the opposing substrate (not shown).

In these cases, one or more of the amplification transistor, selection transistor, reset transistor, and dual conversion transistor disposed on the opposing substrate and the transmission transistor TX disposed on the substrate 400 may be connected to a connection node (not shown).

A floating diffusion region FD may be disposed within the substrate 400. Charges charged in the photodiodes PD may be transmitted to the floating diffusion region FD. The floating diffusion region FD may be configured to maintain charges transmitted from the photodiode PD.

The floating diffusion region FD may be disposed adjacent to the first surface 400a of the substrate 400. The floating diffusion region FD may be buried and disposed from the first surface 400a toward the second surface 400b of the substrate 400. The floating diffusion region FD may be connected to one end of the transmission transistor TX.

The first wiring region 20 is disposed on the first surface 400a of the substrate 400 and may include a plurality of insulating layers IL1, IL2, IL3, a plurality of wiring layers CL1, CL2, and a via VIA.

The insulating layer may include a first insulating layer IL1, a second insulating layer IL2, and a third insulating layer IL3. The first insulating layer IL1, the second insulating layer IL2, and the third insulating layer IL3 may be sequentially stacked on the first surface 400a of the substrate 400.

The first insulating layer IL1 may cover the first surface 400a of the substrate 400. The first insulating layer IL1 may cover the first portion TGa of the transmission gate TG. The second insulating layer IL2 may be disposed on the first insulating layer IL1. The third insulating layer IL3 may be disposed on the second insulating layer IL2.

The first to third insulating layers IL1, IL2, and IL3 may include an insulating material. For example, the first to third insulating layers IL1, IL2, and IL3 may include a silicon-based insulating material such as silicon oxide, silicon nitride, or silicon oxynitride.

The first wiring region 20 may include a first wiring layer CL1 and a second wiring layer CL2. The first wiring layer CL1 may be disposed within a second insulating layer IL2. The second wiring layer CL2 may be disposed within a third insulating layer IL3.

A plurality of vias VIA may be disposed in the first insulating layer IL1, the second insulating layer IL2, and the third insulating layer IL3. The via VIA may connect the floating diffusion region FD, the first wiring layer CL1, and the second wiring layer CL2 to each other.

The first wiring layer CL1, the second wiring layer CL2, and the via VIA may include a metal material. For example, the first wiring layer CL1, the second wiring layer CL2, and the via VIA may include copper (Cu).

The light-transmitting layer 30 may be disposed on the second surface 400b of the substrate 400.

The light-transmitting layer 30 may include an insulating structure 320, a color filter layer CFL, a grid pattern 310, and a micro lens layer MLL.

The light-transmitting layer 30 may collect and filter light incident from the outside and provide the light to the photodiodes PD.

The insulating structure 320 may be disposed between the second surface 400b of the substrate 400 and the color filter layer CFL to be described later, and between the second surface 400b of the substrate 400 and the grid pattern 310 to be described later.

The insulating structure 320 may reduce and/or prevent light reflection so that light incident on the second surface 400b of the substrate 400 may smoothly reach the photodiode PD. The insulating structure 320 may be referred to as an anti-reflection structure.

The insulating structure 320 may include a first fixed charge film 321, a second fixed charge film 323, and a planarization film 325 sequentially stacked on the second surface 400b of the substrate 400.

Each of the first fixed charge film 321, the second fixed charge film 323, and the planarization film 325 may include different materials. The first fixed charge film 321 may include at least one of aluminum oxide, tantalum oxide, titanium oxide, hafnium oxide, and/or the like.

The second fixed charge film 323 may include any one of aluminum oxide, tantalum oxide, titanium oxide, and hafnium oxide. For example, the first fixed charge film 321 may include aluminum oxide, the second fixed charge film 323 may include hafnium oxide, and the planarization film 325 may include silicon oxide.

Although not shown in FIG. 6, in some embodiments, a silicon anti-reflection layer (not shown) may be further disposed between the second fixed charge film 323 and the planarization film 325. The anti-reflection layer may include, for example, silicon nitride.

The color filter layer CFL may be disposed on the second surface 400b of the substrate 400.

In at least one embodiment, the color filter layer CFL (including a plurality of color filters CF) may include multiple layers. For example, the color filter layer CFL may include a lower color filter layer CFL1 and an upper color filter layer CFL2 sequentially stacked on the insulating structure 320. The lower color filter layer CFL1 may include a plurality of lower color filters CFa, and the upper color filter layer CLF2 may include a plurality of upper color filters CFb.

The color filter layer CFL may include the plurality of color filters CF arranged along rows and columns to correspond to each of the plurality of pixels PX.

Each of the plurality of color filters CF may include any one of the plurality of lower color filters CFa included in the lower color filter layer CFL1 and any one of the plurality of upper color filters CFb included in the upper color filter layer CFL2. That is, each of the plurality of color filters CF may include the lower color filter CFa and the upper color filter CFb stacked in the third direction Z, which is a vertical direction.

Specifically, the lower color filter layer CFL1 may include the plurality of lower color filters CFa arranged along rows parallel to the first direction X and columns parallel to the second direction Y on a plane.

The upper color filter layer CFL2 may include a plurality of upper color filters CFb arranged along rows parallel to the first direction X and columns parallel to the second direction Y on a plane so as to overlap each of the plurality of lower color filters CFa included in the lower color filter layer CFL1.

As such, the plurality of lower color filters CFa included in the lower color filter layer CFL1 may overlap with each of the plurality of upper color filters CFb included in the upper color filter layer CFL2 in the third direction Z, which is perpendicular to each other.

In at least one embodiment, the number of lower color filters CFa included in the lower color filter layer CFL1 and the number of upper color filters CFb included in the upper color filter layer CFL2 may be the same. However, the relationship between the number of lower color filters CFa included in the lower color filter layer CFL1 and the number of upper color filters CFb included in the upper color filter layer CFL2 is not limited thereto and may be changed.

The plurality of lower color filters CFa and the plurality of upper color filters CFb may be one of complementary color filters and white filters.

Here, the complementary color filter may refer to a cyan filter, a magenta filter, and a yellow filter, and the white filter may be referred to as a transparent filter or a clear filter. Additionally, unlike cyan filters, magenta filters, and yellow filters that only allow light in specific wavelength bands to pass, white filters may pass light in all wavelength bands.

In at least one embodiment, the plurality of lower color filters CFa and the plurality of upper color filters CFb may be at least one of a cyan filter, a magenta filter, a yellow filter, and a white filter.

The plurality of lower color filters CFa may include different colors from the plurality of upper color filters CFb. That is, some of the plurality of lower color filters CFa may have the same color as the plurality of upper color filters CFb, and some of the rest may have different colors than the plurality of upper color filters CFb.

Additionally, the white filter may be disposed only in either the lower color filter layer CFL1 or the upper color filter layer CLF2. That is, when at least one of the plurality of lower color filters CFa is a white filter, the plurality of upper color filters CFb do not include a white filter. When at least one of the plurality of lower color filters CFa does not include a white filter, at least one of the plurality of upper color filters CFb may be a white filter.

For example, the plurality of lower color filters CFa may be at least one of a magenta filter, a yellow filter, and a white filter, and the plurality of upper color filters CFb may be at least one of a cyan filter, a magenta filter, and a yellow filter. As another example, the plurality of lower color filters CFa may be at least one of a cyan filter, a magenta filter, and a yellow filter, and the plurality of upper color filters CFb may be at least one of a magenta filter, a yellow filter, and a white filter.

Any one of the plurality of lower color filters CFa and any one of the plurality of upper color filters CFb included in each of the plurality of color filters CF may have a different color. That is, the lower color filter CFa and upper color filter CFb, which are included in each of the plurality of color filters CF and overlap in the third direction Z, which is a vertical direction, may have different colors. For example, when the lower color filter CFa is a yellow filter, the upper color filter CFb overlapping the lower color filter CFa may be a cyan filter or a magenta filter. As another example, when the lower color filter CFa is a magenta filter, the upper color filter CFb overlapping the lower color filter CFa may be a yellow filter or a cyan filter. As another example, when the lower color filter CFa is a cyan filter, the upper color filter CFb overlapping the lower color filter CFa may be a yellow filter or a magenta filter. As another example, when the lower color filter CFa is a white filter, the upper color filter CFb overlapping the lower color filter CFa may be any one of a cyan filter, a magenta filter, and a yellow filter. However, this is an example, and the colors of the lower color filter CFa and the upper color filter CFb included in the color filter CF may be changed.

As each of the plurality of color filters CF includes the lower color filter CFa and the upper color filter CFb having different colors, at least some of the plurality of color filters CF may include the color different from the lower color filter CFa and the upper color filter CFb. That is, some of the plurality of color filters CF may have the same color as any one of the lower color filter CFa and the upper color filter CFb (e.g., when the lower color filter CFa is a white filter, the upper color filter CFb overlapping the lower color filter CFa may be any one of a cyan filter, a magenta filter, and a yellow filter), and some of the rest may have a different color from both the lower color filter CFa and the upper color filter CFb.

Here, the color of the color filter CF may refer to the color that appears as the lower color filter CFa and the upper color filter CFb overlap. That is, the color of the color filter CF may refer to a color resulting from a combination of the color of the lower color filter CFa and the color of the upper color filter CFb.

Here, ‘combination’ may refer to a mixture and two or more stacked structures.

Specifically, when the lower color filter CFa included in the color filter CF is any one of a cyan filter, a magenta filter, and a yellow filter, and the upper color filter CFb included in any one of the plurality of color filters CF is another one of a cyan filter, a magenta filter, and a yellow filter, the color filter CF may have a primary color.

For example, if any one of the lower color filter CFa and the upper color filter CFb included in the color filter CF is a cyan filter and the other is a yellow filter, the color filter CF may be a green filter that may filter light in the green spectrum region. As another example, when any one of the lower color filter CFa and the upper color filter CFb included in the color filter CF is a cyan filter and the other is a magenta filter, the color filter CF may be a blue filter that may filter light in the blue spectrum region. As another example, if any one of the lower color filter CFa and the upper color filter CFb included in the color filter CF is a magenta filter and the other is a yellow filter, the color filter CF may be a blue filter that may filter light in the red spectrum region.

In addition, if any one of the lower color filter CFa and the upper color filter CFb included in the color filter CF is a white filter and the other is any one of a cyan filter, a magenta filter, and a yellow filter, the color filter CF may have the same color as the respective cyan filter, magenta filter, and yellow filter.

In at least one embodiment, the plurality of color filters CF may include the first to fourth color filters CF1, CF2, CF3, and CF4 having different colors.

Some of the first to fourth color filters CF1, CF2, CF3, and CF4 may be primary color filters, and some of the rest may be complementary color filters.

The colors of the plurality of color filters CF may be changed in various ways by combining the colors of the lower color filter CFa and the colors of the upper color filter CFb. For example, the plurality of lower color filters CFa included in each of the plurality of color filters CF may include at least two of a magenta filter, a yellow filter, and a white filter. The plurality of upper color filters CFb may include at least two of a cyan filter, a magenta filter, and a yellow filter. The plurality of lower color filters CFa and the plurality of upper color filters CFb may be arranged so that different colors overlap in the vertical direction.

As another example, the plurality of lower color filters CFa included in each of the plurality of color filters CF may include at least two of a cyan filter, a magenta filter, and a yellow filter. The plurality of upper color filters CFb may include at least two of a magenta filter, a yellow filter, and a white filter. The plurality of lower color filters CFa and the plurality of upper color filters CFb may be arranged so that different colors overlap in the vertical direction.

Accordingly, the plurality of color filters CF may include at least three colors.

In at least one embodiment, as shown in FIGS. 3 and 4, any one of a plurality of lower yellow filters Y1 of the lower color filter layer CFL1 may overlap any one of a plurality of upper cyan filters C2 of the upper color filter layer CFL2 to form a first color filter CF1, and the other of the plurality of lower yellow filters Y1 of the lower color filter layer CFL1 may overlap an upper magenta filter M2 of the upper color filter layer CFL2 to form a second color filter CF2. A lower magenta filter M1 of the lower color filter layer CFL1 may overlap another one of the plurality of upper cyan filters C2 of the upper color filter layer CFL2 to form a third color filter CF3, and a white filter W of the lower color filter layer CFL1 may overlap an upper yellow filter Y2 to form a fourth color filter CF4.

Here, the first color filter CF1 may be a green filter, the second color filter CF2 may be a red filter, the third color filter CF3 may be a blue filter, and the fourth color filter CF4 may be a yellow filter.

In some embodiments, a color filter layer CFL_1 shown in FIG. 5 may correspond to the color filter layer CFL shown in FIG. 3. That is, the color filter layer CFL_1 shown in FIG. 5 may include first to fourth color filters CF1, CF2, CF3, and CF4, like the color filter layer CFL shown in FIG. 3.

Specifically, as shown in FIGS. 3 and 5, the lower yellow filter Y1 of a lower color filter layer CFL1_1 may overlap any one of the plurality of upper cyan filters C2 of an upper color filter layer CFL2_1 to form the first color filter CF1. Any one of a plurality of white filters W of the lower color filter layer CFL1_1 may overlap the upper magenta filter M2 of an upper color filter layer CFL2_1 to form the second color filter CF2, another one of the plurality of white filters W of the lower color filter layer CFL1_1 may overlap another of the plurality of upper cyan filters C2 of the upper color filter layer CFL2_1 to form the third color filter CF3, the other one of the plurality of white filters W of the lower color filter layer CFL1_1 may overlap the upper yellow filter Y2 of the upper color filter layer CFL2_1 to form the fourth color filter CF4.

Here, the first color filter CF1 may be a green filter, the second color filter CF2 may be a magenta filter, the third color filter CF3 may be a cyan filter, and the fourth color filter CF4 may be a yellow filter.

In at least one embodiment, the plurality of color filters CF may include first to fourth color filter arrays CFA1, CFA2, CFA3, and CFA4. The first to fourth color filter arrays CFA1, CFA2, CFA3, and CFA4 may be arranged along rows in the first direction X and columns in the second direction Y on a plane, and may overlap the plurality of pixels PX.

Each of the first to fourth color filter arrays CFA1, CFA2, CFA3, and CFA4 may include N×M color filters CF in an N×M array. The N and the M may each independently be an integer greater than 1. For example, each of the first to fourth color filter arrays CFA1, CFA2, CFA3, and CFA4 may include four adjacent color filters CF arranged in two rows and two columns, and the first to fourth color filter arrays CFA1, CFA2, CFA3, and CFA4 may overlap each of the first to fourth pixel groups PG1, PG2, PG3, and PG4.

In each of the first to fourth color filter arrays CFA1, CFA2, CFA3, and CFA4, the plurality of color filters CF may overlap each of the plurality of photodiodes PD in the third direction Z, which is a vertical direction.

Each of the first to fourth color filter arrays CFA1, CFA2, CFA3, and CFA4 includes the first to fourth color filters CF1, CF2, CF3, and CF4 having different colors, and the number of first to fourth color filters CF1, CF2, CF3, and CF4 included in each of the first to fourth color filter arrays CFA1, CFA2, CFA3, and CFA4 may be substantially the same.

In each of the first to fourth color filter arrays CFA1, CFA2, CFA3, and CFA4, the first color filter CF1 and the fourth color filter CF4 may be disposed diagonally to each other, and the second color filter CF2 and the third color filter CF3 may be arranged in two rows and two columns on a plane so that the second color filter CF2 and the third color filter CF3 are disposed diagonally from each other.

In addition, the composition and arrangement of the first to fourth color filters CF1, CF2, CF3, and CF4 included in each of the first to fourth color filter arrays CFA1, CFA2, CFA3, and CFA4 may be the same and/or substantially similar. However, it is not limited thereto, and in some embodiments, the color composition and arrangement of the first to fourth color filters CF1, CF2, CF3, and CF4 included in each of the first to fourth color filter arrays CFA1, CFA2, CFA3, and CFA4 may be different.

The grid pattern 310 may be disposed on the insulating structure 320. The grid pattern 310 may be disposed on the pixel isolation pattern 450 and may overlap at least a portion of the pixel isolation pattern 450 in the third direction Z, which is a vertical direction.

The grid pattern 310 may be disposed within the color filter layer CFL. The grid pattern 310 may be disposed between the plurality of color filters CF. The grid pattern 310 may be disposed at the boundary surface between adjacent color filters CF.

Specifically, the grid pattern 310 may be disposed between the plurality of lower color filters CFa included in the lower color filter layer CFL1. The grid pattern 310 may have a lattice structure on a plane and may surround each of the plurality of lower color filters CFa on a plane.

The thickness of the grid pattern 310 along the third direction Z may be different from the thickness of the plurality of lower color filters CFa along the third direction Z. For example, the thickness of the grid pattern 310 along the third direction Z may be greater than the thickness of the lower color filter CFa along the third direction Z. That is, the upper surface of the grid pattern 310 may be disposed at a higher level than the upper surface of each of the plurality of lower color filters CFa. However, the relationship between the thickness of the grid pattern 310 and the thickness of the lower color filter CFa is not limited thereto and may be changed. For example, the thickness of the grid pattern 310 along the third direction Z and the thickness of the lower color filter CFa along the third direction Z may be substantially the same.

The plurality of upper color filters CFb included in the upper color filter layer CFL2 may cover the upper surface of the lower color filter CFa and the upper surface and side surfaces of the grid pattern 310.

The upper surface and both side surfaces of the grid pattern 310 may be covered by upper color filters CFb adjacent to each other. A portion of the upper surface and one side surface of the grid pattern 310 may be covered by one of the plurality of upper color filters CFb, and the remaining portion of the upper surface and the other side surface of the grid pattern 310 may be covered by another one of the plurality of upper color filters CFb.

A part of the upper color filter CFb may be disposed on the upper surface of the grid pattern 310, and the remaining part may be disposed on the upper surface of the lower color filter CFa. That is, a part of the upper color filter CFb may be disposed on the grid pattern 310 and cover the upper surface of the grid pattern 310, and the remaining part may be disposed between the grid patterns 310 and cover the upper surface of the lower color filter CFa and both side surfaces of the grid pattern 310.

In at least one embodiment, the grid pattern 310 may include at least one of a metal material, a metal nitride, and/or a material having a lower refractive index than the color filter CF. For example, the grid pattern 310 may include at least one organic materials such as titanium (Ti), titanium nitride (TiN), tungsten (W), aluminum (Al), copper (Cu), and a polymer layer containing silica nanoparticles. However, the material included in the grid pattern 310 is not limited thereto and may be changed.

In at least one embodiment, the grid pattern 310 is shown as including a single layer, but in some embodiments, the grid pattern 310 may include multiple layers. For example, the grid pattern 310 may include multiple layers including two or three or more layers, and at least some of each layer included in the grid pattern 310 may include the above-described materials.

In at least one embodiment, the thickness of the plurality of color filters CF along the third direction Z may be substantially the same. For example, the upper surfaces of the plurality of color filters CF may be disposed at the same and/or substantially similar level, and the upper surfaces of the plurality of color filters CF may be substantially flat.

In at least one embodiment, the thickness of the lower color filter CFa included in each of the plurality of color filters CF and the thickness of the upper color filter CFb along the third direction Z may be substantially the same. However, the relationship between the thickness of the lower color filter CFa and the thickness of the upper color filter CFb is not limited thereto and may be changed. For example, the thickness of the lower color filter CFa included in each of the plurality of color filters CF and the thickness of the upper color filter CFb may be different, and the sum of the thickness of lower color filter CFa and the thickness of the upper color filter CFb included in each of the plurality of color filters CF may be substantially the same.

In at least one embodiment, the white filter W is shown as being disposed in the lower color filter layer CFL1, but the position of the white filter W is not limited thereto and may be changed. For example, the white filter W may be disposed on the upper color filter layer CFL2 and may be disposed on at least one of the plurality of lower color filters CFa.

In at least one embodiment, the white filter W disposed in the lower color filter layer CFL1 may serve to eliminate the step between the color filters CF. That is, any one of the plurality of color filters CF, including the white filter W disposed in the lower color filter layer CFL1, may have substantially the same thickness as the another color filter CF, including any one of the lower cyan filter C1, the lower magenta filter M1, and the lower yellow filter Y1, and the two color filters may have substantially flat upper surfaces.

Additionally, as the white filter W is disposed in either the lower color filter layer CFL1 or the upper color filter layer CFL2, the composition of colors included in the color filter CF may be diversified. That is, any one of the plurality of color filters CF including the white filter W may have a different color than any other color filter CF that does not include the white filter W, so that the composition of the colors included in the color filter CF may be diversified by the white filter W.

The micro lens layer MLL may be disposed on the color filter layer CFL.

The micro lens layer MLL may include a flat part MLP and a plurality of micro lenses ML sequentially stacked on the color filter layer CFL. The plurality of micro lenses ML and the flat part MLP may include the same and/or similar materials and may be integrally formed. As such, there may be no boundary between the plurality of micro lenses ML and the flat part MLP.

The flat part MLP of the micro lens layer MLL may entirely cover the color filter layer CFL.

The plurality of micro lenses ML may be disposed on the flat part MLP. The plurality of micro lenses ML may be disposed to correspond to each of the plurality of color filters CF and the plurality of pixels PX. The plurality of micro lenses ML may be arranged in two rows and two columns in each of the first to fourth pixel groups PG1, PG2, PG3, and PG4. That is, in each of the first to fourth pixel groups PG1, PG2, PG3, and PG4, the number of color filters CF and the number of micro lenses ML may be substantially the same.

The upper surface of the plurality of micro lenses ML may include a convex curved surface to refract and collect light incident from the outside. However, the shape of the plurality of micro lenses ML is not limited thereto and may be changed. For example, the upper surface of the plurality of micro lenses ML may have a quadrangle shape with rounded corners.

The micro lens layer MLL may include a light-transmissive polymer material.

In at least one embodiment, the white filter W may include the same material as the micro lens layer MLL. For example, the white filter W may include a light-transmissive polymer material containing at least one of silicon (Si), oxygen (O), and carbon (C). However, this is an example, and the materials included in the white filter W are not limited thereto.

According to the image sensor according to at least one embodiment, the lower color filter CFa and upper color filter CFb, which are included in each of the plurality of color filters CF included in the color filter layer CFL, have different colors and overlap. Accordingly, the plurality of color filters CF may include colors different from the lower color filter CFa and the upper color filter CFb. That is, the plurality of color filters CF may include a primary color filter by combining complementary color filters and a complementary color filter by combining a complementary color filter and a white filter.

Accordingly, the plurality of color filters CF may have various colors by combining the arrangement of the plurality of lower color filters CFa and the arrangement of the plurality of upper color filters CFb. That is, the color selectivity of the plurality of color filters CF and the color isolation characteristics of the image sensor are improved by combining the lower color filter CFa and the upper color filter CFb having different colors, thereby improving the accuracy and resolution of imaging of the plurality of pixels.

In addition, the lower color filter CFa included in each of the plurality of color filters CF includes any one of a complementary color filter and a white filter, and the upper color filter CFb included in each of the plurality of color filters CF includes any one of the complementary color filters. Accordingly, compared to the case where the plurality of color filters CF include one primary color filter, the wavelength range of transmitted light is broadened, thereby improving the sensitivity of the image sensor.

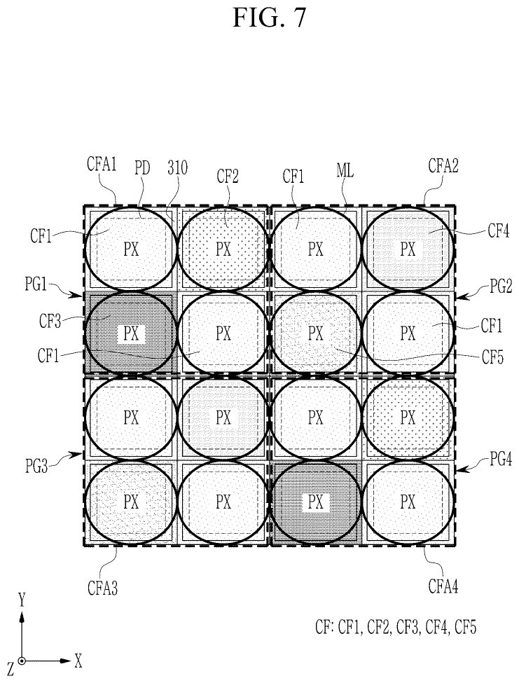

Hereinafter, with reference to FIGS. 7 to 25, image sensors according to various embodiments will be described. In the following embodiments, the same components as the previously described embodiments will be referred to by the same reference numerals, redundant descriptions will be omitted or simplified, and differences will be mainly explained.

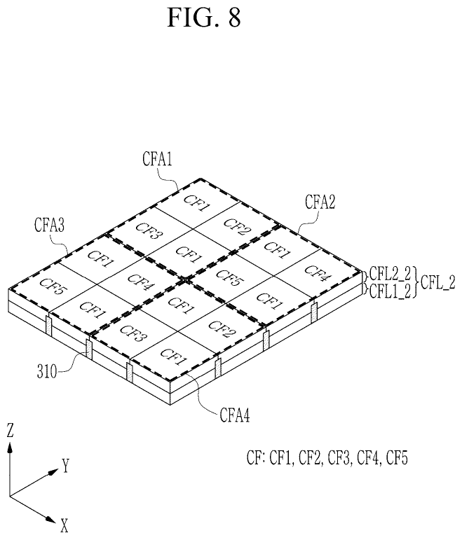

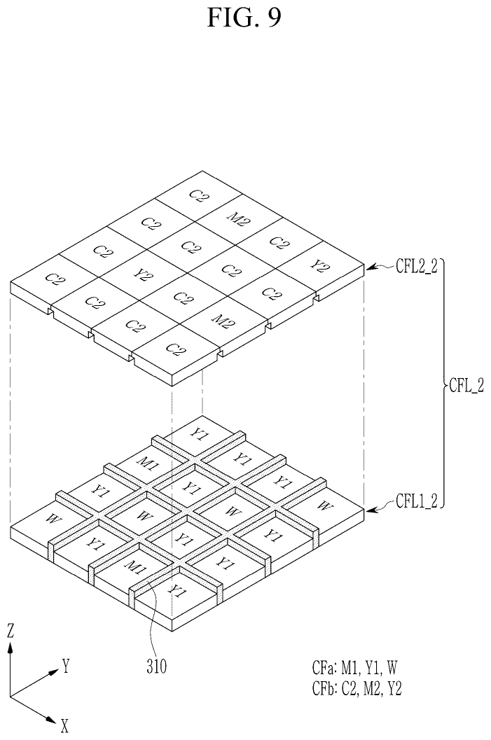

FIG. 7 is a top plan view of an image sensor according to some embodiments. FIG. 8 is a perspective view of a color filter layer included in the image sensor shown in FIG. 7. FIGS. 9 to 11 are exploded perspective views of the color filter layer shown in FIG. 8 according to some embodiments.

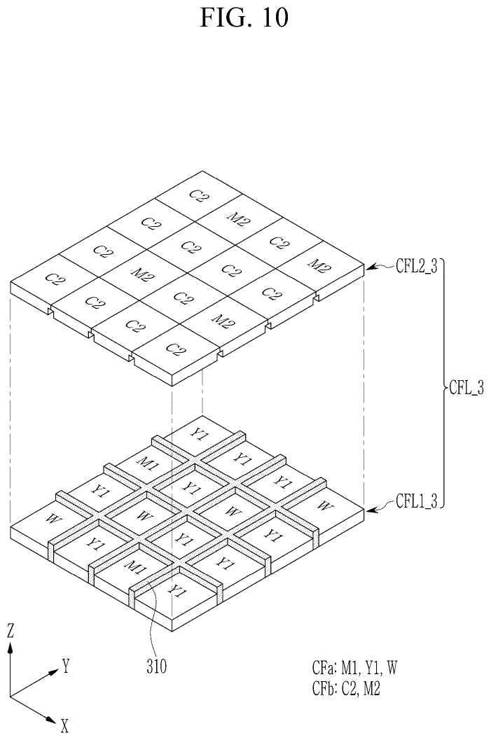

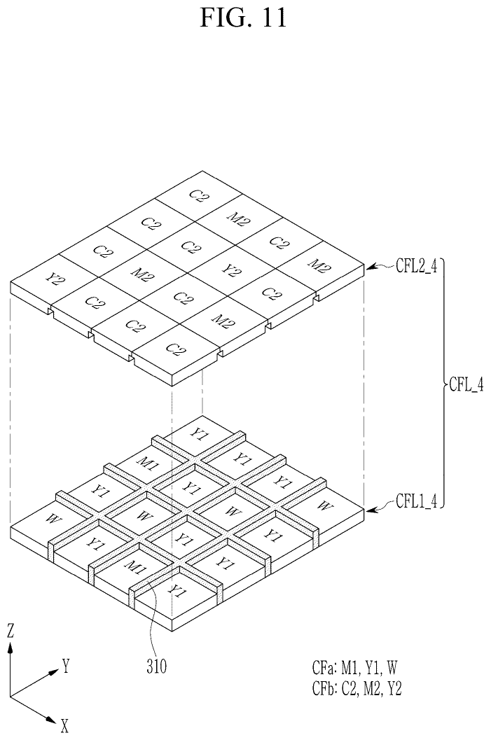

Specifically, color filter layers CFL_3 and CFL_4 shown in FIGS. 10 and 11 may correspond to the color filter layer CFL_2 shown in FIG. 9. That is, the color filter layers CFL_3 and CFL_4 shown in FIGS. 10 and 11 may include first to fifth color filters CF1, CF2, CF3, CF4, and CF5 and first to fourth color filter arrays CFA1, CFA2, CFA3, and CFA4 including the first to fifth color filters CF1, CF2, CF3, CF4, and CF5, like the color filter layer CFL_2 shown in FIG. 9.

The color filter layers CFL_2, CFL_3, and CFL_4 according to the embodiments shown in FIGS. 7 to 11 are different from the color filter layers CFL and CFL_1 according to the embodiments shown in FIGS. 2 to 4 in that the color filter layers CFL_2, CFL_3, and CFL_4 further include a fifth color filter CF5 having a different color from the first to fourth color filters CF1, CF2, CF3, and CF4.

That is, the plurality of color filters CF included in the color filter layers CFL_2, CFL_3, and CFL_4 according to the embodiments shown in FIGS. 7 to 11 may include the first to fifth color filters CF1, CF2, CF3, CF4, and CF5 having different colors.

Some of the first to fifth color filters CF1, CF2, CF3, CF4, and CF5 may be primary color filters, and some of the rest may be complementary color filters.

For example, the first color filter CF1 may be a green filter, the second color filter CF2 may be a red filter, the third color filter CF3 may be a blue filter, the fourth color filter CF4 may be a magenta filter, and the fifth color filter CF5 may be a cyan filter or a yellow filter.

As another example, the first color filter CF1 may be a green filter, the second color filter CF2 may be a red filter, the third color filter CF3 may be a blue filter, the fourth color filter CF4 may be a yellow filter, and the fifth color filter CF5 may be a cyan filter. However, the colors of the first to fifth color filters CF1, CF2, CF3, CF4, and CF5 are not limited thereto and may be changed.

Referring to FIGS. 7 to 11, lower color filter layers CFL1_2, CFL1_3, and CFL1_4 included in each of the color filter layers CFL_2, CFL_3, and CFL_4 may be substantially the same, and upper color filter layers CFL2_2, CFL2_3, and CFL2_4 included in each of the color filter layers CFL_2, CFL_3, and CFL_4 may be different.

The plurality of lower color filters CFa included in each of the lower color filter layers CFL1_2, CFL1_3, and CFL1_4 of the color filters CFL_2, CFL_3, and CFL_4 may have the same and/or substantially similar color compositions and arrangements.

The plurality of upper color filters CFb included in each of the upper color filter layers CFL2_2, CFL2_3, and CFL2_4 of the color filter layers CFL_2, CFL_3, and CFL_4 may have different color composition and arrangement.

In this way, as the color composition of the upper color filters CFb included in the upper color filter layers CFL2_2, CFL2_3, and CFL2_4 in each of the color filter layers CFL_2, CFL_3, and CFL_4 becomes different, the color composition of the plurality of color filters CF included in each of the color filter layers CFL_2, CFL_3, and CFL_4 may be different.

In addition, the color filter layers CFL_2, CFL_3, and CFL_4 according to the embodiments shown in FIGS. 7 to 11 may be different from the color filter layers CFL and CFL_1 according to the embodiments shown in FIGS. 2 to 4 in that the color composition and arrangement of the plurality of color filters CF included in any one of the first to fourth color filter arrays CFA1, CFA2, CFA3, and CFA4 may be different from the composition and arrangement of the plurality of color filters CF included in the other one.

For example, in the first to fourth color filter arrays CFA1, CFA2, CFA3, and CFA4 of the color filter layers CFL_2, CFL_3, and CFL_4 according to the embodiments shown in FIGS. 7 to 11, the plurality of color filters CF included in the first color filter array CFA1 may have the same and/or substantially similar color compositions and arrangements as the plurality of color filters CF included in the fourth color filter array CFA4, and may be different from the color composition and arrangement of the plurality of color filters CF included in each of the second color filter array CFA2 and the third color filter array CFA3.

Additionally, the color composition and arrangement of the plurality of color filters CF included in each of the second color filter array CFA2 and the third color filter array CFA3 may be the same and/or substantially similar.

Specifically, a lower color filter layer CFL1_8 according to the embodiment shown in FIGS. 8 and 9 may include a lower magenta filter M1, a lower yellow filter Y1, and a white filter W, and an upper color filter layer CFL2_8 may include an upper cyan filter C2, an upper magenta filter M2, and an upper yellow filter Y2.

In the first color filter array CFA1 and the fourth color filter array CFA4 of the first to fourth color filter arrays CFA1, CFA2, CFA3, and CFA4 of the color filter layer CFL_2, the lower color filter layer CFL_2 may include a plurality of lower yellow filters Y1 and a lower magenta filter M1, and the upper color filter layer CFL2_2 may include a plurality of upper cyan filters C2 and the upper magenta filter M2.

Some of the plurality of lower yellow filters Y1 may overlap some of the plurality of upper cyan filters C2 to form the plurality of first color filters CF1, the other one of the plurality of lower yellow filters Y1 may overlap the upper magenta filter M2 to form the second color filter CF2, and the lower magenta filter M1 may overlap the other one of the plurality of upper cyan filters C2 to form the third color filter CF3.

In the second color filter array CFA2 and the third color filter array CFA3 of the first to fourth color filter arrays CFA1, CFA2, CFA3, and CFA4, the lower color filter layer CFL_2 may include the plurality of lower yellow filters Y1 and the plurality of white filters W, and the upper color filter layer CFL2_2 may include the plurality of upper cyan filters C2 and the upper yellow filter Y2.

Some of the plurality of lower yellow filters Y1 may overlap some of the plurality of upper cyan filters C2 to form the plurality of first color filters CF1.

Any one of the plurality of white filters W may overlap the upper yellow filter Y2 to form the fourth color filter CF4, and the other one of the plurality of white filters W may overlap the upper cyan filter C2 to form the fifth color filter CF5.

Here, for example, the plurality of first color filter CF1 may be a green filter, the second color filter CF2 may be a red filter, the third color filter CF3 may be a blue filter, the fourth color filter CF4 may be a yellow filter, and the fifth color filter CF5 may be a cyan filter.

In the first color filter array CFA1 and the fourth color filter array CFA4, the first to third color filters CF1, CF2, and CF3 may have a Bayer pattern. In other words, the first to third color filters CF1, CF2, and CF3 may have a pattern where the number of first color filters CF1 is about twice as many as the number of second color filters CF2 or the number of third color filters CF3.

For example, the two first color filters CF1 may be arranged in a diagonal direction, and the second color filter CF2 and the third color filter CF3 may be arranged in a diagonal direction.

Additionally, in the second color filter array CFA2 and the third color filter array CFA3, the first color filter CF1, the fourth color filter CF4, and the fifth color filter CF5 may have a Bayer pattern. That is, the first color filter CF1, the fourth color filter CF4, and the fifth color filter CF5 may have a pattern where the number of the first color filter CF1 is about twice as many as the number of the fourth color filter CF4 or the number of the fifth color filter CF5. For example, the two first color filters CF1 may be arranged in a diagonal direction, and the fourth color filter CF4 and the fourth color filter CF4 may be arranged in a diagonal direction.

In the embodiment according to FIGS. 8 and 9, among the first to fifth color filters CF1, CF2, CF3, CF4, and CF5 included in the color filter layer CFL_2, the number of the first color filter CF1 may be the largest, and the number of each of the second to fifth color filters CF2, CF3, CF4, and CF5 may be the same. That is, the number of green filters may be the largest.

Additionally, the total number of first color filters CF1 included in the color filter layer CFL_2 and the total number of second to fifth color filters CF2, CF3, CF4, and CF5 may be substantially the same. However, the arrangement and number of the first to fifth color filters CF1, CF2, CF3, CF4, and CF5 in each of the first to fourth color filter arrays CFA1, CFA2, CFA3, and CFA4 are not limited thereto and may be changed in various ways.

The plurality of upper color filters CFb included in the upper color filter layer CFL2_3 according to the embodiment shown in FIG. 10 are different from the color composition and arrangement of the plurality of upper color filters CFb included in the upper color filter layer CFL2_3 according to the embodiment shown in FIG. 9.

Accordingly, the color composition and arrangement of the first to fifth color filters CF1, CF2, CF3, CF4, and CF5 included in the color filter layer CFL_3 according to the embodiment shown in FIG. 10 may be different from the color composition and arrangement of the first to fifth color filters CF1, CF2, CF3, CF4, and CF5 included in the color filter layer CFL_2 according to the embodiment shown in FIG. 9.

Specifically, the lower color filter layer CFL1_3 according to the embodiment shown in FIG. 10 may be substantially the same as the lower color filter layer CFL1_2 according to the embodiment shown in FIG. 9.

The upper color filter layer CFL2_3 according to the embodiment shown in FIG. 10 differs from the upper color filter layer CFL2_3 according to the embodiment shown in FIG. 9 in that, in the second color filter array CFA2 and the third color filter array CFA3, the upper yellow filter Y2 may be changed to the upper magenta filter M2. That is, the upper color filter layer CFL2_3 according to the embodiment shown in FIG. 10 may include the plurality of upper cyan filters C2 and the upper magenta filter M2 in the second color filter array CFA2 and the third color filter array CFA3.

Accordingly, in the color filter layer CFL_3 according to the embodiment shown in FIG. 10, in the second color filter array CFA2 and the third color filter array CFA3, the white filter W of the lower color filter layer CFL1_3 and the upper magenta filter M2 of the upper color filter layer CFL2_3 form the fourth color filter CF4, and the fourth color filter CF4 may be a magenta filter. That is, the first color filters CF1 included in the color filter layer CFL_3 according to the embodiment shown in FIG. 10 may be green filters, the second color filter CF2 may be a red filter, the third color filter CF3 may be a blue filter, the fourth color filter CF4 may be a magenta filter, and the fifth color filter CF5 may be a cyan filter.

The composition, arrangement, and number of the first to fifth color filters CF1, CF2, CF3, CF4, and CF5 in each of the first to fourth color filter arrays CFA1, CFA2, CFA3, and CFA4 of the color filter layer CFL_3 according to the embodiment shown in FIG. 10 may be applied substantially the same as the color filter layer CFL_2 according to the embodiment shown in FIG. 9. Therefore, a detailed description thereof is omitted.

The color composition and arrangement of the plurality of upper color filters CFb included in the color filter layer CFL_4 according to the embodiment shown in FIG. 11 are different from the color composition and arrangement of the plurality of upper color filters CFb included in the color filter layer CFL_3 according to the embodiment shown in FIG. 10.

Accordingly, the color composition of the first to fifth color filters CF1, CF2, CF3, CF4, and CF5 included in the color filter layer CFL_4 according to the embodiment shown in FIG. 11 may be different from the color composition of the first to fifth color filters CF1, CF2, CF3, CF4, and CF5 included in the color filter layer CFL_3 according to the embodiment shown in FIG. 10.

Specifically, a lower color filter layer CFL1_4 according to the embodiment shown in FIG. 11 may be substantially the same as the lower color filter layer CFL1_3 according to the embodiment shown in FIG. 10.

An upper color filter layer CFL2_4 according to the embodiment shown in FIG. 11 differs from the upper color filter layer CFL2_3 according to the embodiment shown in FIG. 10 in that, in the second color filter array CFA2 and the third color filter array CFA3, any one of the plurality of the upper cyan filters C2 may be changed to the upper yellow filter Y2.

Accordingly, in the color filter layer CFL_4 according to the embodiment shown in FIG. 11, in the second color filter array CFA2 and the third color filter array CFA3, the white filter W of the lower color filter layer CFL1_4 and the upper yellow filter Y2 of the upper color filter layer CFL2_4 form the fifth color filter CF5, and the fifth color filter CF5 may be a yellow filter. That is, the first color filters CF1 included in the color filter layer CFL_4 according to the embodiment shown in FIG. 11 may be green filters, the second color filter CF2 may be a red filter, the third color filter CF3 may be a blue filter, the fourth color filter CF4 may be a magenta filter, and the fifth color filter CF5 may be a yellow filter.

The composition, arrangement, and number of the first to fifth color filters CF1, CF2, CF3, CF4, and CF5 in each of the first to fourth color filter arrays CFA1, CFA2, CFA3, and CFA4 of the color filter layer CFL_4 according to the embodiment shown in FIG. 11 may be applied the same as and/or substantially similar to the color filter layer CFL_2 according to the embodiment shown in FIG. 9. Therefore, a detailed description thereof is omitted.

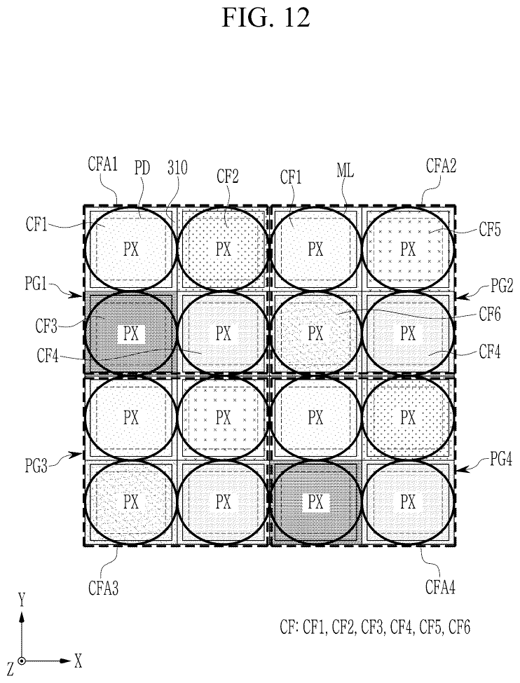

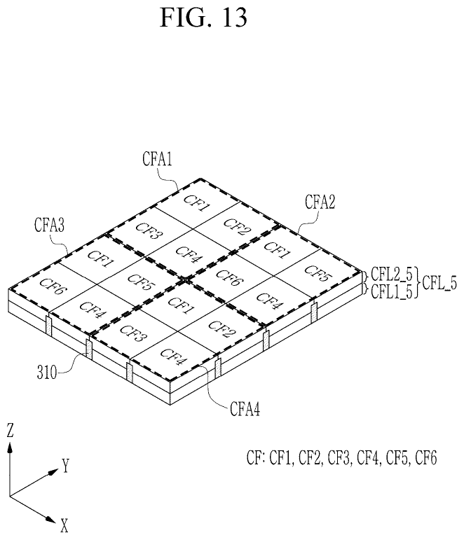

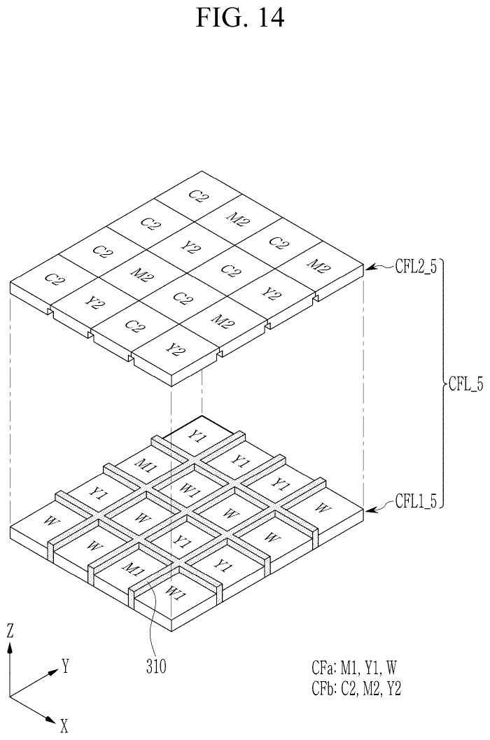

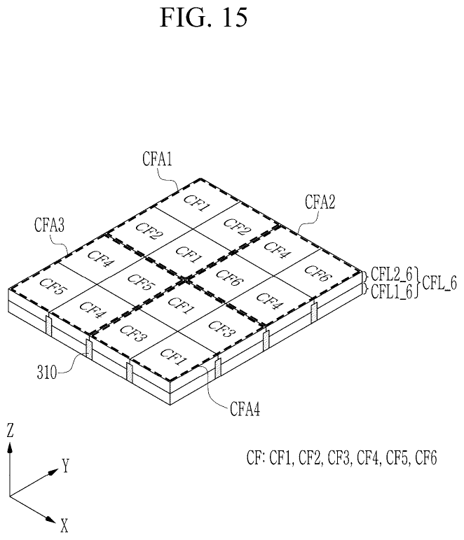

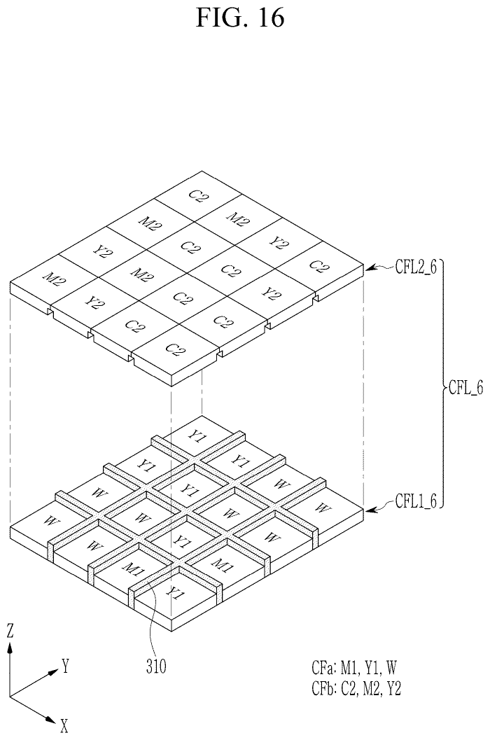

FIG. 12 is a top plan view of an image sensor according to some embodiments. FIG. 13 is a perspective view of a color filter layer included in the image sensor shown in FIG. 12. FIG. 14 is an exploded perspective view of the color filter layer shown in FIG. 13. FIG. 15 is a perspective view of a color filter layer included in an image sensor according to some embodiments. FIG. 16 is an exploded perspective view of the color filter layer shown in FIG. 15.

Color filter layers CFL_5 and CFL_6 according to the embodiments shown in FIGS. 12 to 16 are different from the color filter layers CFL and CFL_1 according to the embodiments shown in FIGS. 2 to 5 in that the color filter layers CFL_5 and CFL_6 further include the fifth color filter CF5 and a sixth color filter CF6 having a different color from the first to fourth color filters CF1, CF2, CF3, and CF4. That is, the color filter layers CFL_5 and CFL_6 according to the embodiments shown in FIGS. 12 to 16 may include the first to sixth color filters CF1, CF2, CF3, CF4, CF5, and CF6 having different colors.

Some of the first to sixth color filters CF1, CF2, CF3, CF4, CF5, and CF6 may be primary color filters, and some of the rest may be complementary color filters.

For example, the first color filter CF1 may be a green filter, the second color filter CF2 may be a red filter, the third color filter CF3 may be a blue filter, the fourth color filter CF4 may be a yellow filter, the fifth color filter CF5 may be a magenta filter, and the sixth color filter CF6 may be a cyan filter. However, this is an example, and the colors of the first to sixth color filters CF1, CF2, CF3, CF4, CF5, and CF6 may be changed.

The color filter layer CFL_5 according to the embodiment shown in FIGS. 12 to 14 may be different from the color filter layers CFL and CFL_1 according to the embodiments shown in FIGS. 2 to 5 in that the color composition and arrangement of the plurality of color filters CF included in any one of the first to fourth color filter arrays CFA1, CFA2, CFA3, and CFA4 may be different from the composition and arrangement of the plurality of color filters CF included in the other one.

For example, in the first to fourth color filter arrays CFA1, CFA2, CFA3, and CFA4, the plurality of color filters CF included in the first color filter array CFA1 may have substantially the same color composition and arrangement as the plurality of color filters CF included in the fourth color filter array CFA4, and may be different from the color composition and arrangement of the plurality of color filters CF included in each of the second color filter array CFA2 and the third color filter array CFA3.

Additionally, the color composition and arrangement of the plurality of color filters CF included in the second color filter array CFA2 and the third color filter array CFA3 may be substantially the same.

Lower color filter layers CFL1_5 and CFL1_6 according to the embodiments shown in FIGS. 12 and 16 may include the lower magenta filter M1, the lower yellow filter Y1, and the white filter W, and the upper color filter layer CFL2_8 may include the upper cyan filter C2, the upper magenta filter M2, and the upper yellow filter Y2.

Specifically, in the first color filter array CFA1 and the fourth color filter array CFA4 of the first to fourth color filter arrays CFA1, CFA2, CFA3, and CFA4, the lower color filter layer CFL1_5 may include the plurality of lower yellow filters Y1, the lower magenta filter M1, and the white filter W, and an upper color filter layer CFL2_5 may include the plurality of upper cyan filters C2, the upper magenta filter M2, and the upper yellow filter Y2.

Any one of the plurality of lower yellow filters Y1 may overlap any one of the plurality of upper cyan filters C2 to form the first color filter CF1, and the other one of the plurality of lower yellow filters Y1 may overlap the upper magenta filter M2 to form the second color filter CF2. The lower magenta filter M1 may overlap another one of the plurality of upper cyan filters C2 to form the third color filter CF3, and the white filter W may overlap the upper yellow filter Y2 to form the fourth color filter CF4.

In addition, in the second color filter array CFA2 and the third color filter array CFA3 of the first to fourth color filter arrays CFA1, CFA2, CFA3, and CFA4, the lower color filter layer CFL1_5 may include the plurality of white filters W and the lower yellow filter Y2, and the upper color filter layer CFL2_5 may include the plurality of upper cyan filters C2, the upper magenta filter M2, and the upper yellow filter Y2.

The lower yellow filters Y1 may overlap any one of the plurality of upper cyan filters C2 to form the first color filter CF1. Any one of the plurality of lower white filters W may overlap the upper yellow filter Y2 to form the fourth color filter CF4, another one of the plurality of lower white filters W may overlap the upper magenta filter M2 to form the fifth color filter CF5, the other one of the plurality of lower white filters W may overlap another one of the plurality of upper cyan filters C2 to form the sixth color filter CF6.

In the first color filter array CFA1 and the fourth color filter array CFA4, the number of first to fourth color filters CF1, CF2, CF3, and CF4 may be the same. In the second color filter array CFA2 and the third color filter array CFA3, the number of first color filters CF1, fourth color filters CF4, fifth color filters CF5, and sixth color filters CF6 may be the same.

Accordingly, the number of the first color filters CF1 included in the color filter layer CFL_5 according to the embodiment shown in FIGS. 12 to 14 may be the same as the number of the fourth color filters CF4. The number of the second color filters CF2, the third color filters CF3, the fifth color filters CF5, and the sixth color filters CF6 included in the color filter layer CFL_5 may be the same.

Accordingly, in the color filter layer CFL_5, the number of the first color filter CF1 or the fourth color filter CF4 may be greater than each of the number of the second color filter CF2, the number of the third color filter CF3, the number of the fifth color filter CF5, and the number of the sixth color filter CF6 included in the color filter layer CFL_5. That is, the sum of the number of first color filters CF1 and the number of fourth color filters CF4 may be the same as the sum of the number of second color filters CF2, the number of third color filters CF3, the number of fifth color filters CF5, and the number of sixth color filters CF6. However, this is an example, and the number of first to sixth color filters CF1, CF2, CF3, CF4, CF5, and CF6 included in the color filter layer CFL_5 may be changed.

Here, the first color filter CF1 may be a green filter, the second color filter CF2 may be a red filter, the third color filter CF3 may be a blue filter, the fourth color filter CF4 may be a yellow filter, the fifth color filter CF5 may be a magenta filter, and the sixth color filter CF6 may be a cyan filter.

The plurality of lower color filters CFa included in the lower color filter layer CFL1_6 according to the embodiments shown in FIGS. 15 and 16 may have a different arrangement than the plurality of lower color filters CFa included in the lower color filter layer CFL1_5 according to the embodiments shown in FIGS. 12 to 14. The plurality of upper color filters CFb included in an upper color filter layer CFL2_6 according to the embodiments shown in FIGS. 15 and 16 may have a different arrangement than the plurality of lower color filters CFa included in the upper color filter layer CFL2_5 according to the embodiment shown in FIGS. 12 to 14.

Accordingly, the plurality of color filters CF included in a color filter layer CFL_6 according to the embodiments shown in FIGS. 15 and 16 may be different from the arrangement of the plurality of color filters CF included in the color filter layer CFL_5 according to the embodiments shown in FIGS. 12 to 14.

Specifically, in each of the first to fourth color filter arrays CFA1, CFA2, CFA3, and CFA4 of the color filter layer CFL_6 according to the embodiments shown in FIGS. 15 and 16, the composition and arrangement of the plurality of color filters CF may be different.

In the first color filter array CFA1, the lower color filter layer CFL1_6 may include the plurality of lower yellow filters Y1, and the upper color filter layer CFL2_6 may include the plurality of upper cyan filters C2 and the plurality of upper magenta filters M2.

Some of the plurality of lower yellow filters Y1 may overlap the plurality of upper cyan filters C2 to form the plurality of first color filters CF1, and some of the rest of the plurality of lower yellow filters Y1 may overlap the plurality of the upper magenta filters M2 to form the plurality of second color filters CF2.

The plurality of first color filters CF1 may be arranged in a diagonal direction, and the plurality of second color filters CF2 may be arranged in a diagonal direction. However, this is an example, and, for example, the arrangement of the first and second color filters CF1 and CF2 may be changed.

In the second color filter array CFA2, the lower color filter layer CFL1_6 may include the plurality of white filters W, and the upper color filter layer CFL2_6 may include the plurality of upper cyan filters C2 and the plurality of upper yellow filters Y2.

Some of the plurality of white filters W may overlap the plurality of upper yellow filters Y2 to form the plurality of fourth color filters CF1, and some of the rest of the plurality of white filters W may overlap the plurality of the upper cyan filters C2 to form the plurality of sixth color filters CF6.

The plurality of fourth color filters CF4 may be arranged in a diagonal direction, and the plurality of sixth color filters CF6 may be arranged in a diagonal direction. However, this is an example, and the arrangement of the fourth and sixth color filters CF4 and CF6 may be changed.

In the third color filter array CFA3, the lower color filter layer CFL1_6 may include the plurality of white filters W, and the upper color filter layer CFL2_6 may include the plurality of upper magenta filters M2 and the plurality of upper yellow filters Y2.

Some of the plurality of white filters W may overlap the plurality of upper yellow filters Y2 to form the plurality of fourth color filters CF4, and some of the rest of the plurality of white filters W may overlap the plurality of the upper magenta filters M2 to form the plurality of fifth color filters CF5.

The plurality of fourth color filters CF4 may be arranged in a diagonal direction, and the plurality of fifth color filters CF5 may be arranged in a diagonal direction. However, this is an example, and the arrangement of the fourth and fifth color filters CF4 and CF5 may be changed.

In the fourth color filter array CFA4, the lower color filter layer CFL1_6 may include the plurality of lower yellow filters Y1 and the plurality of lower magenta filters M1, and the upper color filter layer CFL2_6 may include the plurality of upper cyan filters C2.

The plurality of lower yellow filters Y1 may overlap some of the plurality of upper cyan filters C2 to form the plurality of first color filters CF1, and the plurality of lower magenta filters M1 may overlap some of the rest of the plurality of the upper cyan filters C2 to form the plurality of third color filters CF3.

The plurality of first color filters CF1 may be arranged in a diagonal direction, and the plurality of third color filters CF3 may be arranged in a diagonal direction. However, this is an example, and the arrangement of the first and third color filters CF1 and CF3 may be changed.

The number of first color filters CF1 included in the color filter layer CFL_6 according to the embodiment shown in FIGS. 15 and 16 may be the same as the number of fourth color filters CF4, and the number of second color filters CF2, third color filters CF3, fifth color filters CF5, and sixth color filters CF6 included in the color filter layer CFL_6 may be the same.

The number of the first color filter CF1 or the fourth color filter CF4 may be greater than each of the number of the second color filter CF2, the number of the third color filter CF3, the number of the fifth color filter CF5, and the number of the sixth color filter CF6.

In addition, the sum of the number of first color filters CF1 and the number of fourth color filters CF4 included in the color filter layer CFL_6 may be the same as the sum of the number of second color filters CF2, the number of third color filters CF3, the number of fifth color filters CF5, and the number of sixth color filters CF6. However, this is an example, and the number of first to sixth color filters CF1, CF2, CF3, CF4, CF5, and CF6 included in the color filter layer CFL_6 may be changed.

Here, the first color filter CF1 may be a green filter, the second color filter CF2 may be a red filter, the third color filter CF3 may be a blue filter, the fourth color filter CF4 may be a yellow filter, the fifth color filter CF5 may be a magenta filter, and the sixth color filter CF6 may be a cyan filter.

The image sensor according to the embodiments shown in FIGS. 7 to 16 may have substantially the same effect as the image sensor according to at least one embodiment.

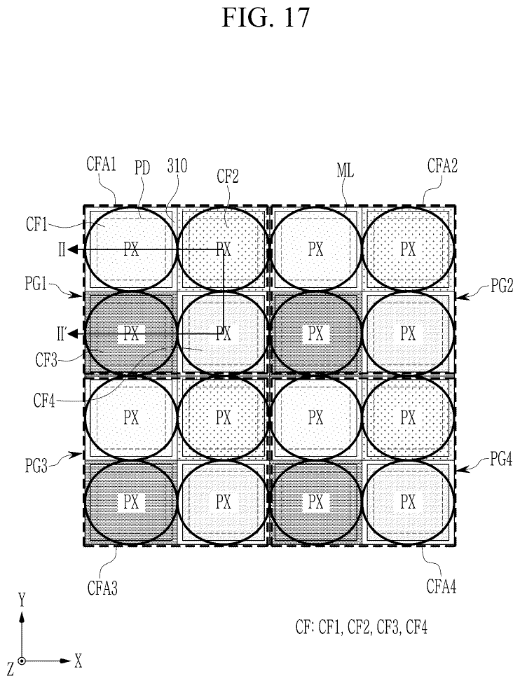

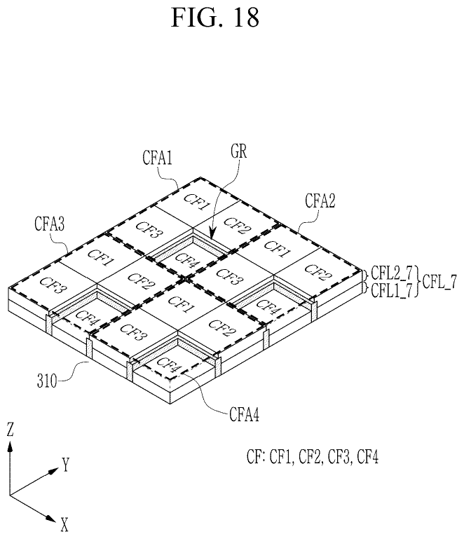

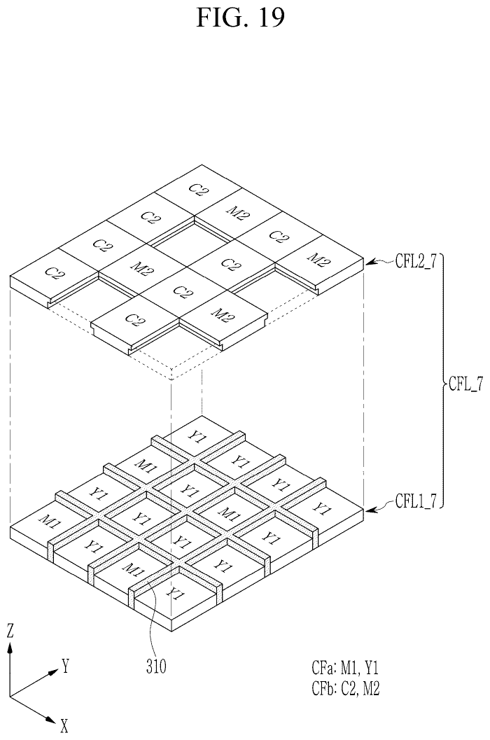

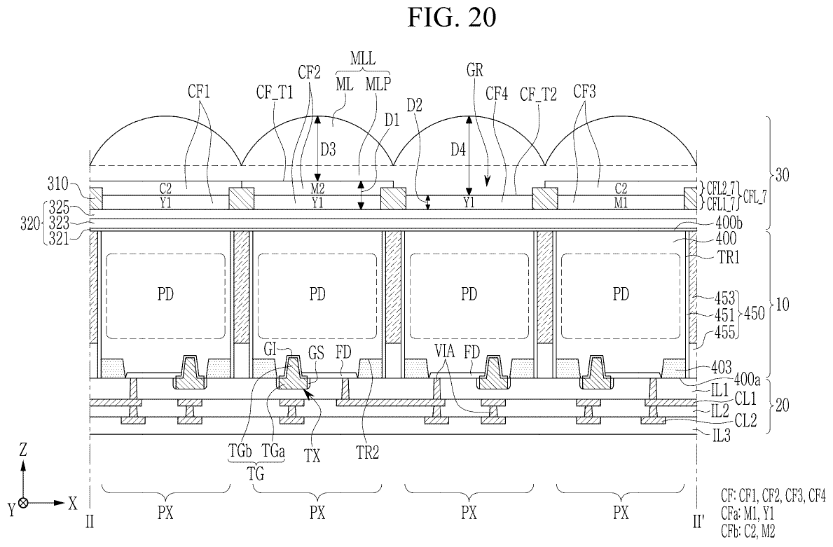

FIG. 17 is a top plan view of an image sensor according to some embodiments. FIG. 18 is a perspective view of a color filter layer included in the image sensor of FIG. 17. FIG. 19 is an exploded perspective view of the color filter layer shown in FIG. 18. FIG. 20 is a cross-sectional view taken along line II-II′ of FIG. 17.

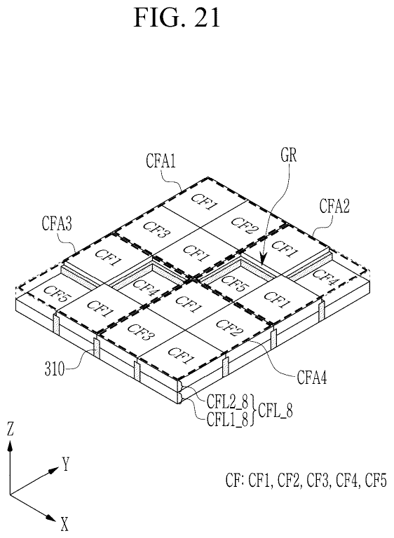

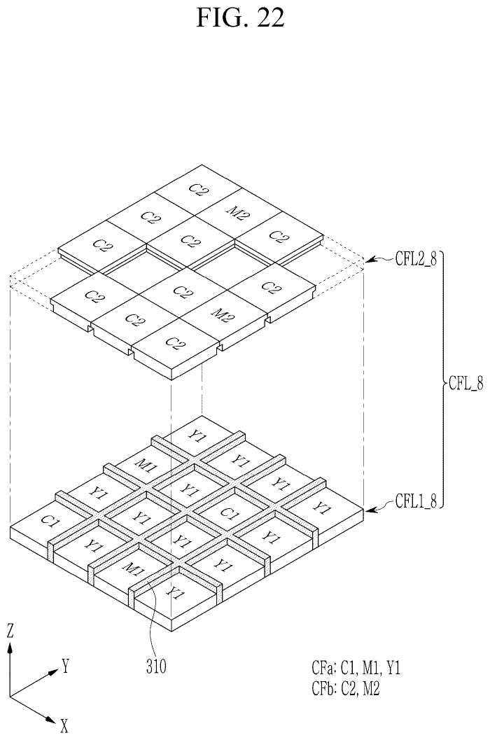

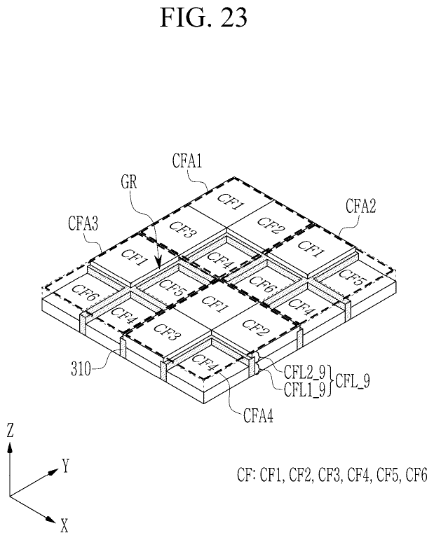

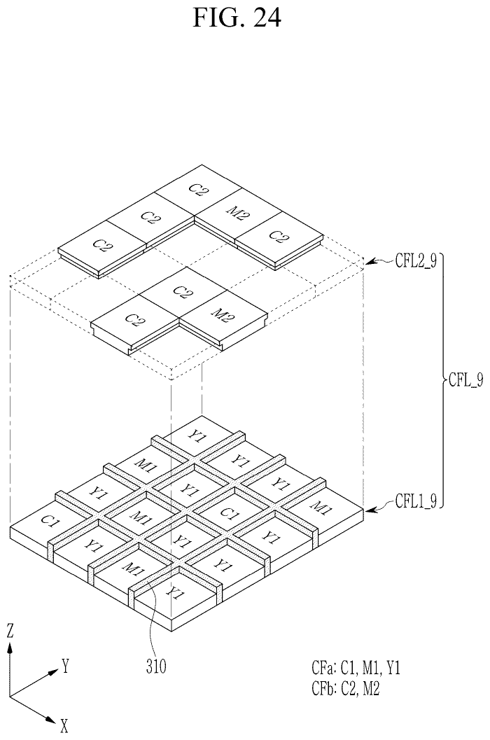

FIGS. 21 and 23 are perspective views of color filter layers included in an image sensor according to some embodiments. FIG. 22 is an exploded perspective view of the color filter layer shown in FIG. 21. FIG. 24 is an exploded perspective view of the color filter layer shown in FIG. 23.

Unlike the embodiments shown in FIGS. 2 to 16, the plurality of lower color filters CFa included in lower color filter layers CFL1_7, CFL1_8, and CFL1_9 and the upper color filters CFb included in upper color filter layers CFL2_7, CFL2_8, and CFL2_9 according to the embodiment shown in FIGS. 17 to 24 may not include the white filter W.

That is, each of the plurality of lower color filters CFa included in the lower color filter layers CFL1_7, CFL1_8, and CFL1_9 and each of the plurality of upper color filters CFb included in the upper color filter layers CFL2_7, CFL2_8, and CFL2_9 according to the embodiments shown in FIGS. 17 to 24 may include at least two of a cyan filter, a magenta filter, and a yellow filter.

Unlike the embodiments shown in FIGS. 2 to 16, the number of lower color filters CFa included in the lower color filter layers CFL1_7, CFL1_8, and CFL1_9 and the number of upper color filters CFb included in the upper color filter layers CFL2_7, CFL2_8, and CFL2_9 according to the embodiments shown in FIGS. 17 to 24 may be different. For example, the number of the plurality of lower color filters CFa included in the lower color filter layers CFL1_7, CFL1_8, and CFL1_9 may be greater than the number of the plurality of upper color filters CFb included in the upper color filter layers CFL2_7, CFL2_8, and CFL2_9.

Some of the plurality of lower color filters CFa may overlap the plurality of upper color filters CFb in the third direction Z, which is a vertical direction, and some of the rest may overlap the upper color filters CFb in the third direction Z, which is a vertical direction.

Each of the plurality of color filters CF of the color filter layers CFL_7, CFL_8, and CFL_9 may include the lower color filters CFa, and some of the plurality of color filters CF may include the upper color filters CFb.

Among the plurality of color filters CF included in the color filter layers CFL_7, CFL_8, and CFL_9, the color filter CF including only the lower color filter CFa may have substantially the same color as the lower color filter CFa.

Some of the plurality of color filters CF of the color filter layers CFL_7, CFL_8, and CFL_9 may include any one of the plurality of lower color filters CFa included in the lower color filter layers CFL1_7, CFL1_8, and CFL1_9 and any one of the plurality of upper color filters CFb included in the upper color filter layers CFL2_7, CFL2_8, and CFL2_9, and some of the rest of the plurality of color filters CF may include only one of the plurality of lower color filters CFa. That is, some of the plurality of color filters CF may include multiple layers including the lower color filter CFa and the upper color filter CFb, and some of the rest may include a single layer including the lower color filter CFa.

The thickness along the third direction Z, which is a vertical direction, of any one color filter CF of the plurality of color filters CF included in the color filter layers CFL_7, CFL_8, and CFL_9 may be different from the thickness along the third direction Z, which is a vertical direction, of the other color filter CF.

Accordingly, a step may exist between any one color filter CF and another color filter CF of the plurality of color filters CF included in the color filter layers CFL_7, CFL_8, and CFL_9. That is, the upper surface of any one of the plurality of color filters CF and the upper surface of another one of the plurality of color filters CF may be disposed at different levels.

The upper color filter layers CFL2_7, CFL2_8, and CFL2_9 disposed on the lower color filter layers CFL1_7, CFL1_8, and CFL1_9 may include empty space that exposes part of the plurality of lower color filters CFa included in the lower color filter layers CFL1_7, CFL1_8, and CFL1_9.

As some of the upper color filters CFb included in the upper color filter layers CFL2_7, CFL2_8, and CFL2_9 disposed on the lower color filter layers CFL1_7, CFL1_8, and CFL1_9 are disposed spaced apart from each other, the upper surface of any one of the plurality of lower color filters CFa and a part of the grid pattern 310 disposed between the plurality of lower color filters CFa may be exposed.

Accordingly, the color filter layers CFL_7, CFL_8, and CFL_9 may include a gap region GR disposed in at least one of the first to fourth color filter arrays CFA1, CFA2, CFA3, and CFA4.

The upper surface of the color filter CF including only the lower color filter CFa among the plurality of color filters CF, and a part of the upper surface and side surface of the grid pattern 310 surrounding the CF may be exposed by the gap region GR.

Here, the gap region GR may refer to a space between the color filters CF including the lower color filter CFa and the upper color filter CFb in the color filter layers CFL_7, CFL_8, and CFL_9.

A step may exist between the color filter CF disposed in the gap region GR and the grid pattern 310 surrounding them. For example, in the gap region GR, the upper surface of the grid pattern 310 may be disposed at a higher level than the upper surface of the color filter CF.

Accordingly, a step may exist between the color filters CF disposed adjacent to the gap region GR among the plurality of color filters CF included in the color filter layers CFL_7, CFL_8, and CFL_9 and the color filter CF disposed in the gap region GR.

Specifically, the plurality of color filters CF included in the color filter layer CFL_7 according to the embodiment shown in FIGS. 17 to 20 may include the first to fourth color filters CF1, CF2, CF3, and CF4, each having different colors.

For example, in at least one embodiment, the lower color filter layer CFL1_7 may include, e.g., the lower magenta filter M1 and the lower yellow filter Y1, and the upper color filter layer CFL2_7 may include the upper cyan filter C2 and the upper magenta filter M2. However, the examples are not limited thereto.

In each of the first to fourth color filter arrays CFA1, CFA2, CFA3, and CFA4, the lower color filter layer CFL1_7 may include the plurality of lower yellow filters Y1 and the lower magenta filter M1, and the upper color filter layer CFL2_7 may include the plurality of upper cyan filters C2 and the upper magenta filter M2.

Any one of the plurality of lower yellow filters Y1 may overlap any one of the plurality of upper cyan filters C2 to form the first color filter CF1, and the other one of the plurality of lower yellow filters Y1 may overlap the upper magenta filter M2 to form the second color filter CF2. The lower magenta filter M1 may overlap another one of the plurality of upper cyan filters C2 to form the third color filter CF3.

Another one of the plurality of lower yellow filters Y1 may form the fourth color filter CF4. That is, unlike the first to third color filters CF1, CF2, and CF3, the fourth color filter CF4 may include only the lower yellow filter Y1.

Here, the first color filter CF1 may be a green filter, the second color filter CF2 may be a red filter, the third color filter CF3 may be a blue filter, and the fourth color filter CF4 may be a yellow filter. However, the colors of the first to fourth color filters CF1, CF2, CF3, and CF4 are not limited thereto, and may be changed in various ways depending on the combination of the arrangement of the lower color filters CFa and the upper color filter CFb.

As shown in FIGS. 18 and 20, the color filter layer CFL_7 may include a plurality of gap regions GR. The plurality of gap regions GR included in the color filter layer CFL_7 may have an island pattern on a plane.

Each of the plurality of gap regions GR may be disposed to overlap the fourth color filter CF4 in the third direction Z, which is a vertical direction, in each of the first to fourth color filter arrays CFA1, CFA2, CFA3, and CFA4.

The gap region GR included in the color filter layer CFL_7 may be surrounded by the second color filter CF2 and the third color filter CF3 disposed in the first color filter array CFA1, the third color filter CF3 disposed in the second color filter array CFA2, and the second color filter CF2 disposed in the fourth color filter array CFA4.

The gap region GR may expose a part of the upper and side surfaces of the grid pattern 310 surrounding the fourth color filter CF4 and an upper surface CF_T2 of the fourth color filter CF4.

In the gap region GR, the fourth color filter CF4 and the grid pattern 310 may have a step. That is, the upper surface CF_T2 of the fourth color filter CF4 may be disposed at a lower level than the upper surface of the grid pattern 310.

As shown in FIGS. 18 and 20, as the first to third color filters CF1, CF2, and CF3 include multiple layers and the fourth color filter CF4 includes a single layer, the first to third color filters CF1, CF2, and CF3 and the fourth color filter CF4 may have a step. That is, an upper surface CF_T1 of the first to third color filters CF1, CF2, and CF3 may be disposed at a higher level than the upper surface CF_T2 of the fourth color filter CF4.

Each of the first to third color filters CF1, CF2, and CF3 may have a first thickness D1 in the third direction Z, the fourth color filter CF4 may have a second thickness D2 in the third direction Z, and the first thickness D1 may be greater than the second thickness D2.

That is, the thickness of the first to third color filters CF1, CF2, and CF3 along the third direction Z may be substantially the same, and the thickness of the first to third color filters CF1, CF2, and CF3 along the third direction Z may be greater than the thickness of the fourth color filter CF4 along the third direction Z. However, the position of the gap region GR and the thickness relationship of the color filters CF may be changed in various ways depending on the arrangement of the plurality of lower color filters CFa included in the lower color filter layer CFL1_7 and the plurality of upper color filters CFb included in the upper color filter layer CFL2_7, and a combination thereof.

As shown in FIG. 20, the micro lens layer MLL disposed on the color filter layer CFL_7 may entirely cover the color filter layer CFL_7.

A part of the flat part MLP of the micro lens layer MLL may be disposed within the gap region GR. That is, part of the flat part MLP of the micro lens layer MLL may be disposed on the color filter CF disposed within the gap region GR, and the remaining part may be disposed on the color filter CF adjacent to the gap region GR.

The flat part MLP of the micro lens layer MLL may entirely cover the upper and side surfaces of the grid pattern 310 disposed within the gap region GR and the upper surface of the color filter CF.

Accordingly, the micro lens layer MLL may serve to flatten the step between any one of the plurality of color filters CF and another one.

The micro lens layer MLL disposed on the color filters CF adjacent to the gap region GR may have a third thickness D3 along the third direction Z, and the micro lens layer MLL disposed in the gap region GR may have a fourth thickness D4 along the third direction Z, and the third thickness D3 may be smaller than the fourth thickness D4.

Here, the third thickness D3 may refer to the thickness along the third direction Z of the micro lens layer MLL disposed on the upper surface CF_T1 of the color filters CF adjacent to the gap region GR, and the fourth thickness D4 may refer to the thickness along the third direction Z of the micro lens layer MLL disposed on the upper surface CF_T2 of the color filter CF in the gap region GR. For example, the third thickness D3 may refer to the sum of the thicknesses of the flat part MLP and the micro lens ML disposed on the color filters CF adjacent to the gap region GR, and the fourth thickness D4 may refer to the sum of the thicknesses of the flat part MLP and the micro lens ML disposed on the color filter CF in the gap region GR.

For example, the micro lens layer MLL disposed on the upper surface CF_T1 of the first to third color filters CF1, CF2, and CF3 adjacent to the gap region GR may have the third thickness D3, and the micro lens layer MLL disposed on the upper surface CF_T2 of the fourth color filter CF4 in the gap region GR may have the fourth thickness D4.

As shown in FIG. 20, the sum of the first thickness D1 and the third thickness D3 may be substantially equal to the sum of the second thickness D2 and the fourth thickness D4. Therefore, the sum of the thicknesses of the first to third color filters CF1, CF2, and CF3 adjacent to the gap region GR and the micro lens layer MLL disposed thereon may be substantially equal to the sum of the thicknesses of the fourth color filter CF4 and the micro lens layer MLL disposed on the fourth color filter CF4 in the gap region GR.

Accordingly, an acme of the upper surface of the micro lens layer MLL disposed on the color filter layer CFL_7, (e.g., the upper surface of the plurality of micro lenses ML) may be disposed at substantially the same level. Here, the upper surface of the plurality of micro lenses ML may refer to the upper surface of the thickest part of the micro lenses ML.

A color filter layer CFL_8 according to the embodiment shown in FIGS. 21 and 22 may include first to fifth color filters CF1, CF2, CF3, CF4, and CF5 having different colors.

Specifically, the lower color filter layer CFL1_8 may include the lower cyan filter C1, the lower magenta filter M1, and the lower yellow filter Y1, and the upper color filter layer CFL2_8 may include the upper cyan filter C2 and the upper magenta filter M2.

In the present embodiment, in the first color filter array CFA1 and the fourth color filter array CFA4 of the first to fourth color filter arrays CFA1, CFA2, CFA3, and CFA4 of the color filter layer CFL_8, the lower color filter layer CFL_8 may include the plurality of lower yellow filters Y1 and the lower magenta filter M1, and the upper color filter layer CFL2_8 may include the plurality of upper cyan filters C2 and the upper magenta filter M2.

Some of the plurality of lower yellow filters Y1 may overlap some of the plurality of upper cyan filters C2 to form the plurality of first color filters CF1, some of the rest of the plurality of lower yellow filters Y1 may overlap the upper magenta filter M2 to form the second color filter CF2, and the lower magenta filter M1 may overlap some of the rest of the plurality of upper cyan filters C2 to form the third color filter CF3.

In addition, in the second color filter array CFA2 and the third color filter array CFA3 among the first to fourth color filter arrays CFA1, CFA2, CFA3, and CFA4 of the color filter layer CFL_8, the lower color filter layer CFL_8 may include the plurality of lower yellow filters Y1 and the lower cyan filter C1, and the upper color filter layer CFL2_8 may include the plurality of upper cyan filters C2.

Some of the lower yellow filters Y1 may overlap some of the upper cyan filters C2 and form the plurality of first color filters CF1.

Some of the rest of the plurality of lower yellow filters Y1 may form the fourth color filter CF4, and the lower cyan filter C1 may form the fifth color filter CF5. That is, the fourth color filter CF4 may include only the lower yellow filter Y1 unlike the first to third color filters CF1, CF2, and CF3, and the fifth color filter CF5 may include only the lower cyan filter C1 unlike the first to third color filters CF1, CF2, and CF3.

Here, the first color filter CF1 may be a green filter, the second color filter CF2 may be a red filter, the third color filter CF3 may be a blue filter, the fourth color filter CF4 may be a yellow filter, and the fifth color filter CF5 may be a cyan filter. However, the colors of the first to fifth color filters CF1, CF2, CF3, CF4, and CF5 are not limited thereto, and may be changed in various ways by the color composition, arrangement, and combination of the plurality of lower color filters CFa included in the lower color filter layer CFL1_8 and the plurality of upper color filters CFb included in the upper color filter layer CFL2_8.

The color filter layer CFL_8 may include the plurality of gap regions GR, which may have an island pattern on a plane.

The plurality of gap regions GR may be disposed in the second color filter array CFA2 and the third color filter array CFA3 among the first to fourth color filter arrays CFA1, CFA2, CFA3, and CFA4. That is, the plurality of gap regions GR may be disposed to overlap the fourth color filter CF4 and the fifth color filter CF5 in the third direction Z, which is a vertical direction, in each of the second color filter array CFA2 and the third color filter array CFA3.

The gap region GR included in the color filter layer CFL_8 may be surrounded by the first color filter CF1 disposed in each of the first color filter array CFA1 and the fourth color filter array CFA4, and the first color filter CF disposed in the third color filter array CFA3.

As the first to third color filters CF1, CF2, and CF3 included in the color filter layer CFL_8 include multiple layers, and the fourth color filter CF4 and the fifth color filter CF5 include a single layer, the first to third color filters CF1, CF2, and CF3, and the fourth color filter CF4 and the fifth color filter CF5 may have a step.

Further, the thicknesses of the first to third color filters CF1, CF2, and CF3 along the third direction Z may be greater than each of the thicknesses of the fourth color filter CF4 and the fifth color filter CF5 along the third direction Z, and the thicknesses of the fourth color filter CF4 and the fifth color filter CF5 along the third direction Z may be substantially the same. However, the position of the gap region GR and the thickness relationship of the color filters CF may be changed in various ways depending on the arrangement of the plurality of lower color filters CFa included in the lower color filter layer CFL1_8 and the plurality of upper color filters CFb included in the upper color filter layer CFL2_8, and a combination thereof.

Although not shown in FIGS. 21 and 22, a micro lens layer (see ‘MLL’ in FIG. 20) may be disposed on the color filter layer CFL_8 according to the present embodiment.

That is, as described above, the micro lens layer MLL disposed on the color filter layer CFL_8 may serve to flatten the step between any one of the plurality of color filters CF and another one.

The plurality of color filters CF included in a color filter layer CFL_9 according to the embodiment shown in FIGS. 23 and 24 may include the first to sixth color filters CF1, CF2, CF3, CF4, CF5, and CF6 having different colors.

Some of the first to sixth color filters CF1, CF2, CF3, CF4, CF5, and CF6 may be primary color filters, and some of the rest may be complementary color filters.

Specifically, the lower color filter layer CFL1_7 may include the lower cyan filter C1, the lower magenta filter M1, and the lower yellow filter Y1, and the upper color filter layer CFL2_7 may include the upper cyan filter C2 and the upper magenta filter M2.

In the first color filter array CFA1 and the fourth color filter array CFA4 of the first to fourth color filter arrays CFA1, CFA2, CFA3, and CFA4 of the color filter layer CFL_9, the lower color filter layer CFL1_9 may include the plurality of lower yellow filters Y1 and the lower magenta filter M1, and an upper color filter layer CFL2_9 may include the plurality of upper cyan filters C2 and the upper magenta filter M2.

Any one of the plurality of lower yellow filters Y1 may overlap any one of the plurality of upper cyan filters C2 to form the first color filter CF1, and the other one of the plurality of lower yellow filters Y1 may overlap the upper magenta filter M2 to form the second color filter CF2. The lower magenta filter M1 may overlap another one of the plurality of upper cyan filters C2 to form the third color filter CF3.

Another one of the plurality of lower yellow filters Y1 may form the fourth color filter CF4. That is, unlike the first to third color filters CF1, CF2, and CF3, the fourth color filter CF4 may include only the lower yellow filter Y1.

In addition, in the second color filter array CFA2 and the third color filter array CFA3 among the first to fourth color filter arrays CFA1, CFA2, CFA3, and CFA4 of the color filter layer CFL_9, the lower color filter layer CFL1_9 may include the plurality of lower yellow filters Y1, the lower magenta filter M1, and the lower cyan filter C1, and the upper color filter layer CFL2_9 may include an upper cyan filter C2.

Any one of the plurality of lower yellow filters Y1 may overlap the upper cyan filter C2 to form the first color filter CF1.

Another one of the plurality of lower yellow filters Y1 may form the fourth color filter CF4, the lower magenta filter M1 may form the fifth color filter CF5, and the lower cyan filter C1 may form the sixth color filter CF6. That is, unlike the first to third color filters CF1, CF2, and CF3, the fourth color filter CF4, the fifth color filter CF5, and the sixth color filter CF6 may include only the lower color filter CFa.

Here, the first color filter CF1 may be a green filter, the second color filter CF2 may be a red filter, the third color filter CF3 may be a blue filter, the fourth color filter CF4 may be a yellow filter, the fifth color filter CF5 may be a magenta filter, and the sixth color filter CF6 may be a cyan filter. However, the colors of the first to sixth color filters CF1, CF2, CF3, CF4, CF5, and CF6 are not limited thereto, and may be changed in various ways by the color composition, arrangement, and combination of the plurality of lower color filters CFa included in the lower color filter layer CFL1_9 and the plurality of upper color filters CFb included in the upper color filter layer CFL2_9.

As the first to third color filters CF1, CF2, and CF3 included in the color filter layer CFL_9 include multiple layers, and the fourth to sixth color filter CF4, CF5, and CF6 include a single layer, the first to third color filters CF1, CF2, and CF3, and the fourth to sixth color filters CF4, CF5, and CF6 may have a step.

In addition, the thickness of the first to third color filters CF1, CF2, and CF3 in the third direction Z may be greater than the thickness of the fourth to sixth color filters CF4, CF5, and CF6 in the third direction Z.

The thickness of the first to third color filters CF1, CF2, and CF3 in the third direction Z may be the same and/or substantially similar, and the thickness of the fourth to sixth color filters CF4, CF5, and CF6 in the third direction Z may be the same and/or substantially similar.

The color filter layer CFL_9 may include the plurality of gap regions GR, and the gap regions GR may have a line shape on a plane. That is, the gap region GR may overlap the plurality of lower color filters CFa disposed on any one of the first to fourth color filter arrays CFA1, CFA2, CFA3, and CFA4 and another one, and may be extended in the first direction X and the second direction Y.

For example, the gap region GR may overlap the fourth color filter CF4 disposed in the first color filter array CFA1, the fourth to sixth color filters CF4, CF5, and CF6 disposed in the second color filter array CFA2, and the fourth to sixth color filters CF4, CF5, and CF6 disposed in the third color filter array CFA3 in the third direction Z, which is a vertical direction.

The gap region GR disposed in each of the first color filter array CFA1, the second color filter array CFA2, and the third color filter array CFA3 may be integrally formed, and may have a line shape on a plane as the gap region GR extends along the first direction X and the second direction Y.

The gap region GR included in the color filter layer CFL_9 may be at least partially surrounded by the first to third color filters CF1, CF2, and CF3 disposed in each of the first color filter array CFA1 and the fourth color filter array CFA4, and by the first color filter CF1 disposed in each of the second color filter array CFA2 and the third color filter array CFA3.

However, the position of the gap region GR and the thickness relationship of the color filters CF may be changed in various ways depending on the arrangement of the plurality of lower color filters CFa included in the lower color filter layer CFL1_9 and the plurality of upper color filters CFb included in the upper color filter layer CFL2_9, and a combination thereof.

Although not shown in FIGS. 23 and 24, a micro lens layer (see ‘MLL’ in FIG. 20) may be disposed on the color filter layer CFL_9 according to the present embodiment.

That is, as described above, the micro lens layer MLL disposed on the color filter layer CFL_9 may serve to flatten the step between any one of the plurality of color filters CF and another one.

The image sensor according to the embodiments shown in FIGS. 17 to 24 may configure the color filters CF included in the color filter layers CFL_7, CFL_8, and CFL_9 into various colors without adding a separate process step, and may have substantially the same effect as the image sensor according to the embodiments shown in FIGS. 1 to 16.

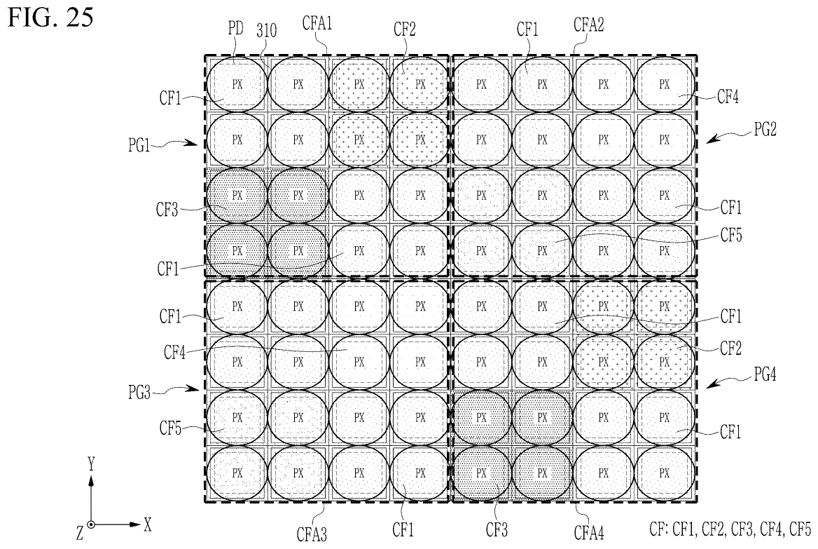

FIG. 25 is a top plan view of an image sensor according to some embodiments.

The embodiment shown in FIG. 25 differs from the embodiments shown in FIGS. 1, 7, and 12 in that the number of pixels PX included in each of the first to fourth pixel groups PG1, PG2, PG3, and PG4 varies.

In addition, the embodiment shown in FIG. 25 differs from the embodiments shown in FIGS. 1, 7, and 12 in that the number of pixels PX that overlaps the color filter CF in each of the first to fourth color filter arrays CFA1, CFA2, CFA3, and CFA4.

Specifically, referring to FIG. 25, each of the first to fourth pixel groups PG1, PG2, PG3, and PG4 may include 16 adjacent pixels PX arranged in four rows and four columns. However, this is an example, and the number of pixels PX included in each of the first to fourth pixel groups PG1, PG2, PG3, and PG4 may be changed in various ways.

Each of the first to fourth color filter arrays CFA1, CFA2, CFA3, and CFA4 may include four adjacent color filters CF arranged in two rows and two columns, and the first to fourth color filter arrays CFA1, CFA2, CFA3, and CFA4 may be arranged to correspond to each of the first to fourth pixel groups PG1, PG2, PG3, and PG4.

In the first to fourth color filter arrays CFA1, CFA2, CFA3, and CFA4, the color filters CF may be disposed to correspond to a plurality of pixels PX. For example, in the first to fourth color filter arrays CFA1, CFA2, CFA3, and CFA4, one color filter CF may be disposed to correspond to four adjacent pixels PX arranged in two rows and two columns. In other words, one color filter CF may overlap four pixels PX.

As one color filter CF is disposed to correspond to the plurality of pixels PX, one color filter CF may overlap the plurality of photodiodes PD in the third direction Z, which is a vertical direction. For example, one color filter CF may overlap four adjacent photodiodes PD arranged in two rows and two columns in the third direction Z, which is a vertical direction. However, the number of pixels PX or photodiodes PD overlapping the color filter CF is not limited thereto and may be changed in various ways. For example, one color filter CF may be disposed to correspond to nine adjacent pixels PX arranged in three rows and three columns. As another example, one color filter CF may be disposed to correspond to four adjacent pixels PX arranged in four rows and four columns.

In the present embodiment, the color filter CF may include the first to fifth color filters CF1, CF2, CF3, CF4, and CF5 having different colors. Some of the first to fifth color filters CF1, CF2, CF3, CF4, and CF5 may be primary color filters, and some of the rest may be complementary color filters.

For example, the first color filter CF1 may be a green filter, the second color filter CF2 may be a red filter, the third color filter CF3 may be a blue filter, the fourth color filter CF4 may be a magenta filter, and the fifth color filter CF5 may be a cyan filter or a yellow filter.

As another example, the first color filter CF1 may be a green filter, the second color filter CF2 may be a red filter, the third color filter CF3 may be a blue filter, the fourth color filter CF4 may be a yellow filter, and the fifth color filter CF5 may be a cyan filter. However, the colors of the first to fifth color filters CF1, CF2, CF3, CF4, and CF5 are not limited thereto and may be changed in various ways.

In each of the first to fourth color filter arrays CFA1, CFA2, CFA3, and CFA4, the color filters CF may have a Bayer pattern.

Specifically, the first color filter array CFA1 and the fourth color filter array CFA4 may include first to third color filters CF1, CF2, and CF3, and the first to third color filters CF1, CF2, and CF3 may have a Bayer pattern. That is, in the first color filter array CFA1 and the fourth color filter array CFA4, the number of first color filters CF1 may have about twice as many patterns as the number of second color filters CF2 or the number of third color filters CF3.

In the first color filter array CFA1 and the fourth color filter array CFA4, the first to third color filters CF1, CF2, and CF3 may be arranged such that the first color filter CF1 is disposed diagonally to each other, and the second color filter CF2 and the third color filter CF3 are disposed diagonally to each other.

In addition, the second color filter array CFA2 and the third color filter array CFA3 may include the first color filter CF1, the fourth color filter CF4, and the fifth color filter CF5. The color filter CF1, the fourth color filter CF4, and the fifth color filter CF5 may be arranged in a Bayer pattern. That is, in the second color filter array CFA2 and the third color filter array CFA3, the first color filter CF1, the fourth color filter CF4, and the fifth color filter CF5 may have a pattern where the number of the first color filter CF1 is about twice as many as the number of the fourth color filter CF4 or the number of the fifth color filter CF5.

In the second color filter array CFA2 and the third color filter array CFA3, the first color filter CF1, the fourth color filter CF4, and the fifth color filter CF5 may be arranged such that the first color filters CF1 are disposed diagonally to each other, and the fourth color filter CF4 and the fifth color filter CF5 are disposed diagonally to each other. However, this is an example, and the composition and arrangement of the color filter CF included in the first to fourth color filter arrays CFA1, CFA2, CFA3, and CFA4 are not limited thereto and may be changed in various ways. For example, each of the first to fourth color filter arrays CFA1, CFA2, CFA3, and CFA4 includes the first to fourth color filters CF1, CF2, CF3, and CF4 having different colors, and the color filters CF included in each of the first to fourth color filter arrays CFA1, CFA2, CFA3, and CFA4 may be arranged substantially the same as the color filters CF according to the embodiment shown in FIG. 2.

As another example, each of the first to fourth color filter arrays CFA1, CFA2, CFA3, and CFA4 includes the first to sixth color filters CF1, CF2, CF3, CF4, CF5, and CF6 having different colors, and the color filters CF included in each of the first to fourth color filter arrays CFA1, CFA2, CFA3, and CFA4 may be arranged substantially the same as the color filters CF according to the embodiment shown in FIG. 12.

In FIG. 25, the plurality of micro lenses ML are shown as arranged to correspond to each of the plurality of pixels PX, however, the arrangement of the plurality of micro lenses ML is not limited thereto and may be changed in various ways.

For example, the plurality of micro lenses ML may be arranged to correspond to each of the first to fourth pixel groups PG1, PG2, PG3, and PG4. That is, the plurality of micro lenses ML may be arranged to correspond to four adjacent pixels PX arranged in two rows and two columns. As another example, the plurality of micro lenses ML may be arranged to correspond to nine adjacent pixels PX arranged in three rows and three columns.

The image sensor according to the embodiment shown in FIG. 25 may have substantially the same effect as the image sensor according to the embodiment.

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. An image sensor, comprising:
a substrate;
a plurality of photodiodes in the substrate;
a pixel isolation pattern between the plurality of photodiodes;
a color filter layer including a lower color filter layer and an upper color filter layer sequentially stacked on the plurality of photodiodes; and
a micro lens layer on the color filter layer,
wherein the color filter layer comprises a plurality of color filters corresponding to the plurality of photodiodes,
the lower color filter layer comprises a plurality of lower color filters each having at least one color of first to fourth colors, and each of the plurality of color filters comprises a respective one of the plurality of lower color filters, and
the upper color filter layer comprises a plurality of upper color filters each having at least one color of the first to fourth colors, and at least some of the plurality of color filters further comprise a respective one of the plurality of upper color filters, and
at least some of the plurality of color filters have colors different from the first to fourth colors.

2. The image sensor of claim 1, wherein
the first color is white, the second color is yellow, the third color is magenta, and the fourth color is cyan.

3. The image sensor of claim 2, wherein
the plurality of color filters comprises at least first to fourth color filters having different colors.

4. The image sensor of claim 3, wherein
the first color filter is a green filter,
the second color filter is a red filter,
the third color filter is a blue filter,
and the fourth color filter is one of a yellow filter, a magenta filter, or a cyan filter.

5. The image sensor of claim 3, wherein
the first color filter is a yellow filter,
the second color filter is a magenta filter,
the third color filter is a cyan filter,
and the fourth color filter is one of a red filter, a green filter, or a blue filter.

6. The image sensor of claim 3, wherein
the plurality of color filters further comprises a fifth color filter having a different color from the first to fourth color filters.

7. The image sensor of claim 6, wherein the color filter layer comprises
a first color filter array and a second color filter array including the plurality of color filters,
the first color filter array comprises the first color filter, the second color filter, and the third color filter,
and the second color filter array comprise the first color filter, the fourth color filter, and the fifth color filter.

8. The image sensor of claim 7, wherein in the first color filter array,
a quantity of the first color filters is equal to a sum of the second color filters and the third color filters, and
in the second color filter array,
a quantity of the first color filters is equal to a sum of the fourth color filters and the fifth color filters.

9. The image sensor of claim 8, wherein
the first color filter is a green filter,
the second color filter is a red filter,
the third color filter is a blue filter,
the fourth color filter is a magenta filter,
and the fifth color filter is one of a cyan filter, or a yellow filter.

10. The image sensor of claim 8, wherein
the first color filter is a green filter,
the second color filter is a red filter,
the third color filter is a blue filter,
the fourth color filter is a yellow filter,
and the fifth color filter is a cyan filter.

11. The image sensor of claim 6, wherein the plurality of color filters further comprise
a sixth color filter having a different color from the first to fifth color filters, and
wherein the first color filter is a green filter,
the second color filter is a red filter,
the third color filter is a blue filter,
the fourth color filter is a yellow filter,
the fifth color filter is a magenta filter, and
the sixth color filter is a cyan filter.

12. The image sensor of claim 11, wherein the color filter layer comprises
first to fourth color filter arrays including the plurality of color filters, and
wherein the first color filter array comprises the first color filter and the second color filter,
the second color filter array comprises the first color filter and the third color filter,
the third color filter array comprises the fourth color filter and the fifth color filter, and
the fourth color filter array comprises the fourth color filter and the sixth color filter.

13. The image sensor of claim 11, wherein the color filter layer comprises
a first color filter array and a second color filter array including the plurality of color filters, and
wherein the first color filter array comprises the first to fourth color filters, and
the second color filter array comprises the first color filter, the fourth color filter, the fifth color filter, and the sixth color filter.

14. The image sensor of claim 1, further comprising:
a plurality of grid patterns on the pixel isolation pattern,
wherein each of the plurality of lower color filters is between the plurality of grid patterns, and
each of the plurality of upper color filters covers the plurality of lower color filters and the plurality of grid patterns.

15. An image sensor, comprising:
a substrate;
a plurality of photodiodes in the substrate;
a pixel isolation pattern between the plurality of photodiodes;
a color filter layer including a lower color filter layer and an upper color filter layer sequentially stacked on the plurality of photodiodes; and
a micro lens layer on the color filter layer,
wherein the color filter layer comprises a plurality of color filters corresponding to the plurality of photodiodes,
the lower color filter layer comprises a plurality of lower color filters each having at least one color of white, yellow, magenta, or cyan, and each of the plurality of color filters comprises a respective one of the plurality lower color filters,
the upper color filter layer comprises a plurality of upper color filters each having at least one color of the white, the yellow, the magenta, or the cyan, and each of the plurality of color filters comprises a respective one of the plurality upper color filters,
at least some of the plurality of color filters have a different color from the white filter, the yellow filter, the magenta filter, and the cyan filter, and
each of the plurality of color filters has substantially the same thickness.

16. The image sensor of claim 15, wherein
the plurality of lower color filters has at least two colors of the white, the yellow, or the magenta,
the plurality of upper color filters has at least two colors of the yellow, the magenta, or the cyan, and
the plurality of color filters have at least four colors of a red filter, a green filter, a blue filter, a yellow filter, a magenta filter, or a cyan filter.

17. An image sensor, comprising:
a substrate;
a plurality of photodiodes in the substrate;
a pixel isolation pattern between the plurality of photodiodes;
a color filter layer including a lower color filter layer and an upper color filter layer sequentially stacked on the plurality of photodiodes; and
a micro lens layer on the color filter layer,
wherein the micro lens layer comprises a flat part covering the color filter layer and a plurality of micro lenses on the flat part,
the color filter layer comprises a plurality of color filters corresponding to the plurality of photodiodes,
the lower color filter layer comprises a plurality of lower color filters each having at least one color of yellow, magenta, and cyan, and each of the plurality of color filters comprises a respective one of the plurality of lower color filters,
the upper color filter layer comprises a plurality of upper color filters each having at least one color of the yellow, the magenta, and the cyan, and at least some of the plurality of color filters comprise a respective one of the plurality of upper color filters,
at least some of the plurality of color filters have a different color from the yellow filter, the magenta filter, and the cyan filter, and
a thickness of at least one of the plurality of color filters is different from a thickness of another one of the plurality of color filters.

18. The image sensor of claim 17, wherein a quantity of the plurality of lower color filters and a quantity of the upper color filters are different, and
the plurality of color filters have at least four of a red filter, a green filter, a blue filter, a yellow filter, a magenta filter, or a cyan filter.

19. The image sensor of claim 18, wherein the plurality of color filters comprises a first color filter and a second color filter having the different thicknesses, and
a sum of a thickness of the first color filter and a thickness of a corresponding one of the micro lens layer on the first color filter is substantially equal to a sum of the thickness of the second color filter and the thickness of a corresponding one of the micro lens layer on the second color filter.

20. The image sensor of claim 19, wherein the plurality of upper color filters comprise
a first upper color filter and a second upper color filter spaced apart from each other in a horizontal direction and with at least one lower color filter therebetween,
and the flat part of the micro lens layer is between the first upper color filter and the second upper color filter.
